(19) United States
(12) Patent Application Publication
(10) Pub. No.: US 2026/0270334 A1
(43) Pub. Date: Sep. 10, 2026

(54) WEARABLE DEVICE INCLUDING FLEXIBLE DISPLAY

(71) Applicant: SAMSUNG ELECTRONICS CO., LTD., Suwon-si (KR)

(72) Inventor: Hunyoung RYU, Suwon-si (KR)

(73) Assignee: SAMSUNG ELECTRONICS CO., LTD., Suwon-si (KR)

(21) Appl. No.: 19/662,409

(22) Filed: Apr. 29, 2026

Related U.S. Application Data
(63) Continuation of application No. PCT/KR2024/016843, filed on Oct. 30, 2024.

(30) Foreign Application Priority Data
Dec. 22, 2023 (KR) 10-2023-0189656
Feb. 8, 2024 (KR) 10-2024-0019768

(51) Int. Cl. H04M 1/02; G04G 17/04; G04G 17/08; H10H 29/49; H10K 59/131; H10K 102/00

(52) U.S. Cl. CPC H04M 1/0268; G04G 17/045; G04G 17/08; H04M 1/0274; H04M 1/0277; H10H 29/49; H10K 59/131; H10K 2102/311

(57) ABSTRACT

A wearable electronic device is provided. The wearable electronic device includes a frame, a first strap and a second strap which respectively extend from sides of the frame, and a display disposed on the frame, the first strap, and the second strap. The display includes a display panel, a first bending part, a second bending part, a first driving circuit disposed on a substrate extending through the first bending part, a second driving circuit disposed on a substrate of the display panel extending through the second bending part, first wires extending from the first driving circuit and connected to scan lines and data lines in a first display area of the display panel through the first bending part, and second wires extending from the second driving circuit and connected to scan lines and data lines in a second display area of the display panel through the second bending part.

### CROSS-REFERENCE TO RELATED APPLICATIONS

This application is a continuation of International Application No. PCT/KR2024/016843 designating the United States, filed on October 30, 2024, in the Korean Ministry of Intellectual Property Receiving Office and claiming priority to Korean Patent Application Nos. 10-2023-0189656, filed on December 22, 2023, and 10-2024-0019768, filed on February 8, 2024, in the Korean Ministry of Intellectual Property, the disclosures of each of which are incorporated by reference herein in their entireties.

### FIELD

The present disclosure is directed to wearable electronic devices and, more particularly, to a wearable device including a flexible display.

### BACKGROUND

Since a wearable device is used by being worn on a body of a user, reducing weight and size of the wearable device may improve user comfort and portability. The wearable device may include structures for expanding a display area of a display disposed in the miniaturized wearable device. In the miniaturized device including the expanded display, electronic components may need a disposition that may increase space efficiency.

The above-described information may be provided as a related art for the purpose of helping understanding of the present disclosure. No argument or decision is made as to whether any of the above descriptions may be applied as a prior art related to the present disclosure.

### SUMMARY

According to an aspect, a wearable electronic device may include a frame. The wearable device may include a first strap and a second strap. The first strap may extend from a first portion of a side surface of the frame. The second strap may extend from a second portion of the side surface of the frame in a direction opposite to an extension direction of the first strap. The wearable electronic device may include a flexible display. The flexible display may be disposed on the frame, the first strap, and the second strap. The flexible display may include a display panel. The display may include a first bending part. The first bending part may extend from a first side of the display panel and bent into a space surrounded by the frame. The flexible display may include a second bending part. The second bending part may extend from a second side of the display panel and bent into the space surrounded by the frame. The flexible display may further include first driving circuitry. The first driving circuitry may be disposed on a substrate of the display panel extending through the first bending part. The flexible display may include second driving circuitry. The second driving circuitry may be disposed on a substrate of the display panel extending through the second bending part. The flexible display may include first wires. The first wires may extend from the first driving circuitry and electrically connected to scan lines and data lines in a first display area of the display panel through the first bending part. The flexible display may include a second wires. The second wires may extend from the second driving circuitry and electrically connected to scan lines and data lines in a second display area of the display panel through the second bending part.

According to another aspect, a wearable electronic device may include a frame including a side wall. The wearable electronic device may include a plurality of straps. The plurality of straps may be extended from the side wall of the frame. The wearable electronic device may include a display. The display may be disposed on the frame and the plurality of straps. The display may include a first driving circuitry. The first driving circuitry may be disposed in a space surrounded by the side wall of the frame and configured to drive pixels in a first display area of the display. The display may include a second driving circuitry. The second driving circuitry may be disposed in the space and configured to drive pixels in a second display area of the display. The frame may include slits formed in partition walls of the frame through which a portion of the display disposed on the plurality of straps passes and the slits may be disposed in inactive areas of the display.

### BRIEF DESCRIPTION OF THE DRAWINGS

FIG. 1A is a perspective view of a front surface of a mobile electronic device according to an embodiment of the present disclosure.

FIG. 1B is a perspective view of a rear surface of the electronic device of FIG. 1A according to an embodiment of the present disclosure.

FIG. 1C is an exploded perspective view of the electronic device of FIG. 1A according to an embodiment of the present disclosure.

FIG. 2 is a diagram representing an exemplary display including a plurality of driving circuitries according to an embodiment of the present disclosure.

FIG. 3A illustrates an exemplary disposition in which a plurality of exemplary driving circuitries included in a display face each other according to an embodiment of the present disclosure.

FIG. 3B represents a disposition of an exemplary bending part of a display including a plurality of driving circuitries according to an embodiment of the present disclosure.

FIG. 3C represents a disposition of an exemplary bending part of a display including one driving circuitry according to an embodiment of the present disclosure.

FIG. 4A represents an example in which each of a plurality of exemplary driving circuitries included in a display is disposed next to each other according to an embodiment of the present disclosure.

FIG. 4B exemplarily represents display areas controlled by each of a plurality of exemplary driving circuitries included in a display according to an embodiment of the present disclosure.

FIGS. 5A, 5B, and 5C exemplarily represent touch patterns connected to a plurality of driving circuitries according to various embodiments of the present disclosure.

FIG. 6 is a diagram representing a connection structure between a bending part of a display panel and a printed circuit board according to an embodiment of the present disclosure.

FIG. 7 represents an exemplary structure included in a frame to visually separate a display area according to an embodiment of the present disclosure.

FIG. 8A represents a support plate disposed below a display panel and configured to bend a strap according to an embodiment of the present disclosure.

FIG. 8B represents a cross-section of a support plate according to an embodiment of the present disclosure.

FIGS. 9A, 9B, and 9C represent an exemplary disposition of a plurality of driving circuitries included in a display according to various embodiments of the present disclosure.

FIG. 10 is a block diagram of an electronic device in a network environment according to an embodiment of the present disclosure.

### DETAILED DESCRIPTION

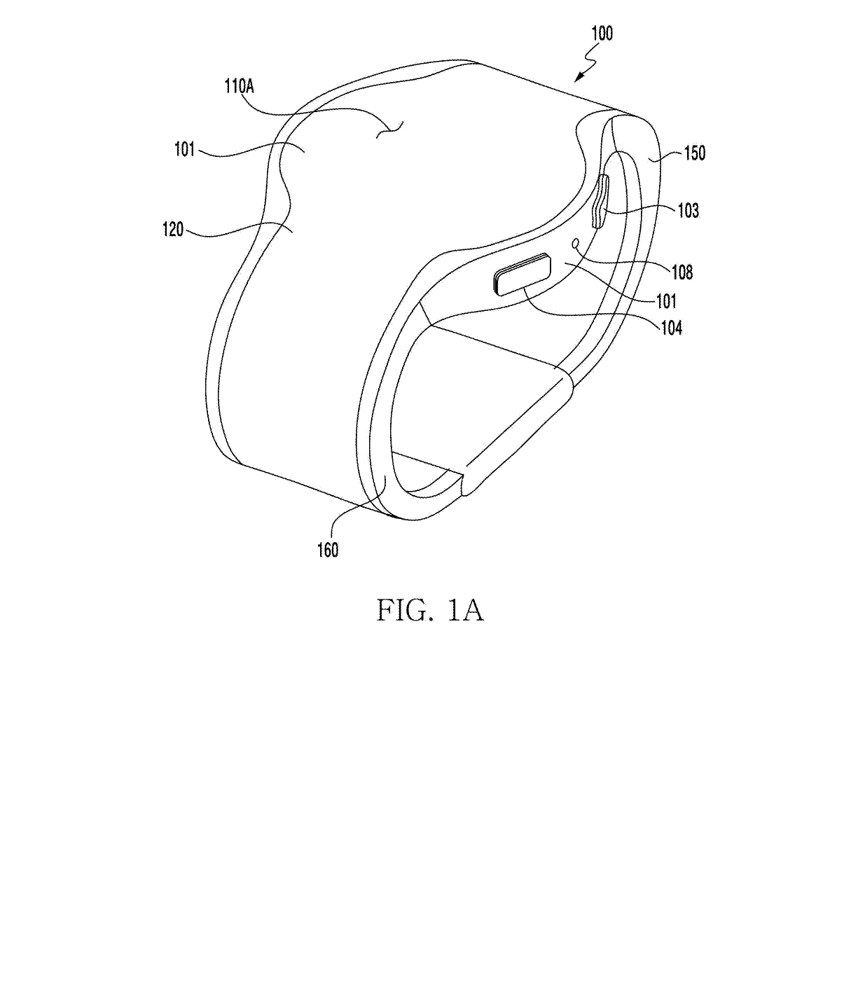

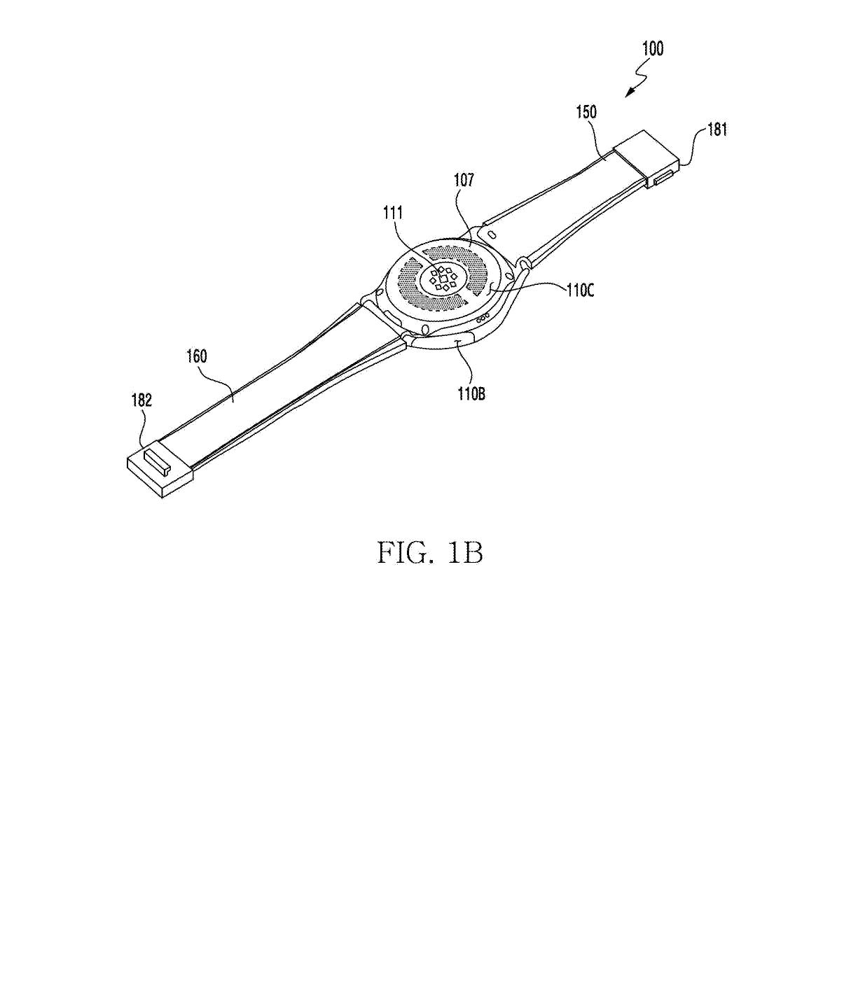

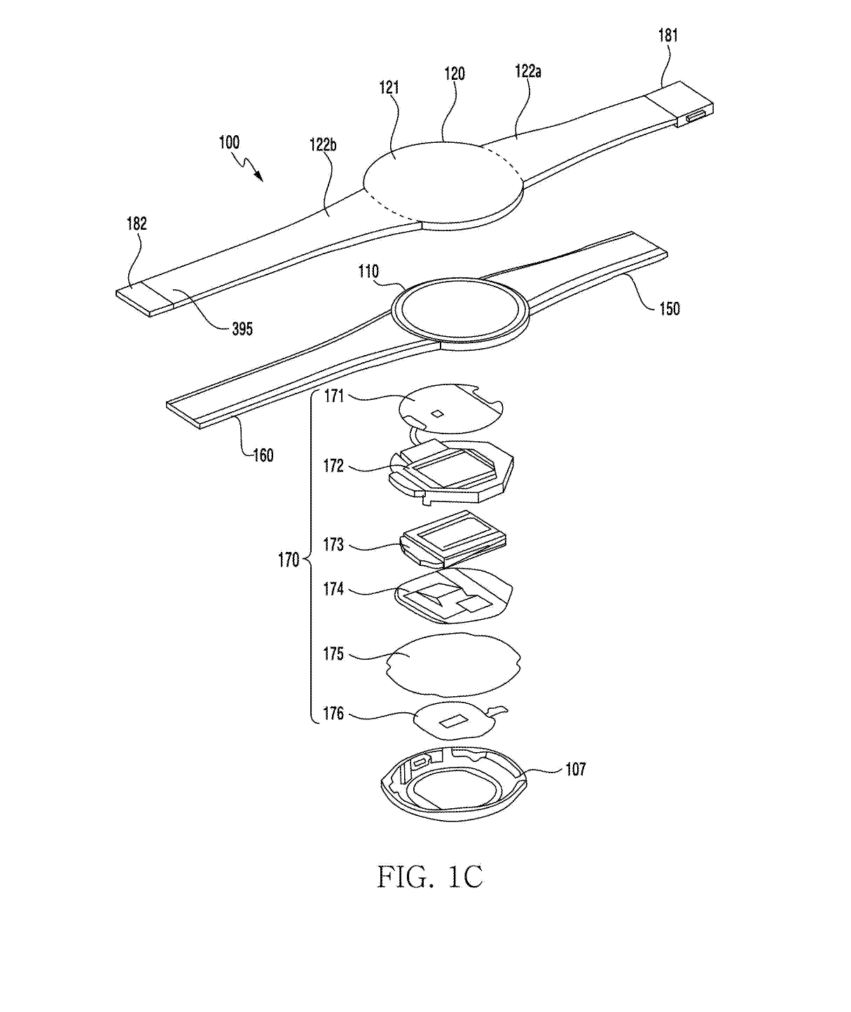

FIG. 1A is a perspective view of a front surface of a mobile electronic device according to an embodiment. FIG. 1B is a perspective view of a rear surface of the electronic device of FIG. 1A. FIG. 1C is an exploded perspective view of the electronic device of FIG. 1A.

Referring to FIGS. 1A and 1B, an electronic device 100 according to an embodiment may include a frame 110 including a first surface (or a front surface) 110A and a side surface 110B surrounding an inner space, and a rear plate 107 including a second surface (or a rear surface) 110C spaced apart from the first surface 110A of the frame 110 and in contact with the side surface 110B to surround the inner space. The electronic device 100 may include straps 150 and 160 extending from a portion of the side surface 110B of the frame 110 and configured to allow the electronic device 100 to be detachably attached to a part (e.g., a wrist, an ankle, and the like) of a body of a user. The frame 110 including the first surface 110A and the side surface 110B, and the rear plate 107 including the second surface 110C may be referred to as a housing in terms of providing an exterior of the electronic device 100.

At least a portion of the first surface 110A may be formed by a substantially transparent front plate 101 (e.g., a glass plate including various coating layers, or a polymer plate). The front plate 101 may be disposed on the frame 110, the first strap 150, and the second strap 160. The front plate 101 may be configured to have rigidity on the frame 110 and to have flexibility on the first strap 150 and the second strap 160. For example, a portion of the front plate 101 disposed on the frame 110 may be thicker than remaining portions (e.g., a portion of the front plate 101 disposed on the first strap 150 and the second strap 160). A material of at least a portion of the portion of the front plate 101 disposed on the frame 110 may be different from that of the remaining portions.

The second surface 110C may be formed by a substantially opaque rear plate 107. The rear plate 107 may be formed of, for example, coated or colored glass, ceramic, polymer, metal (e.g., aluminum, stainless steel (STS), or magnesium), or a combination of at least two of the above materials.

The side surface 110B may be coupled to the front plate 101 and the rear plate 107 and may be formed by the frame 110 including metal and/or polymer. The straps 150 and 160 may be formed of various materials and shapes. The straps 150 and 160 may include fluor elastomers (FKM) or another flexible material. For example, the straps 150 and 160 may be integrally formed of an injection-molded material, rubber, urethane, ceramic, or a combination of at least two of the above materials.

The frame 110 and the straps 150 and 160 may be integrally formed. For example, the frame 110 and the straps 150 and 160 may be coupled through an injection process and integrally formed. The frame 110 may be formed of metal and polymer having rigidity, and the straps 150 and 160 injected into the frame 110 may be formed of a material having flexibility. The frame 110 and the straps 150 and 160 may include an interlocking structure or a corrugated structure to prevent separation after injection. In the integrally formed frame 110 and straps 150 and 160, a portion in contact with a display 120 may be formed as a continuous surface.

According to an embodiment, the electronic device 100 may include at least one of the display 120, audio devices 105 and 108, a sensor module 111, and key input devices 103 and 104. In some embodiments, the electronic device 100 may omit at least one of components (e.g., the key input devices 103 and 104, or the sensor module 111) or may additionally include another component.

The display 120 may be exposed, for example, through a significant portion of the front plate 101. A shape of the display 120 may be a shape corresponding to a shape of the front plate 101. The display 120 may be integrally formed on the frame 110, the first strap 150, and the second strap 160. For example, the shape of the display 120 may be a shape corresponding to a shape of the frame 110, the first strap 150, and the second strap 160. A portion of the display 120 disposed on the frame 110 may have various shapes, such as a circular shape, an elliptical shape, or a polygonal shape, according to a shape of the frame 110. A portion of the display 120 disposed on the first strap 150 and the second strap 160 may have a band shape extending from the frame 110. The display 120 may be coupled to or disposed adjacent to touch sensing circuitry, a pressure sensor capable of measuring an intensity (a pressure) of a touch, and/or a fingerprint sensor.

The audio devices 105 and 108 may include a microphone hole 105 and a speaker hole 108. A microphone for obtaining an external sound may be disposed inside the microphone hole 105, and in some embodiments, a plurality of microphones may be disposed to detect a direction of a sound. The speaker hole 108 may be used as an external speaker and a call receiver. In some embodiments, the speaker hole and the microphone hole may be implemented as one hole, or a speaker without a speaker hole (e.g., a piezo speaker) may be included.

The sensor module 111 may generate an electrical signal or a data value corresponding to an internal operating state of the electronic device 100 or an external environmental state. The sensor module 111 may include, for example, a biometric sensor module 111 (e.g., an HRM sensor) disposed on the second surface 110C of the frame 110. The electronic device 100 may further include at least one sensor module not illustrated, for example, a gesture sensor, a gyro sensor, a barometric sensor, a magnetic sensor, an acceleration sensor, a grip sensor, a color sensor, an infrared (IR) sensor, a biometric sensor, a temperature sensor, a humidity sensor, or an illuminance sensor.

The key input devices 103 and 104 may include a key button disposed on the side surface 110B of the frame 110. The key input devices 103 and 104 may be implemented in another form such as a soft key and the like on the display 120.

Fastening members 181 and 182 may be configured to fasten the frame 110 and the straps 150 and 160 to a part (e.g., a wrist, an ankle, and the like) of the body of the user. The first fastening member 181 and the second fastening member 182 may be coupled to each other to fasten the frame 110 and the straps 150 and 160 to a part of the body of the user. The fastening members 181 and 182 may be formed in a buckle shape.

Referring to FIG. 1C, the electronic device 100 may include an electrical component 170. The electronic device 100 may include the rear plate 107, the frame 110, the display 120, the first strap 150, the second strap 160, a first antenna 171, a support member 172 (e.g., a bracket), a battery 173, a PCB 174, a sealing member 175, and a second antenna 176. At least one of components of the electronic device 100 may be omitted, and another component may be added. The support member 172 may be disposed inside the electronic device 100 to be connected to the frame 110, or may be integrally formed with the frame 110. The frame 110 may be referred to as a side bezel structure in terms of determining a shape of a side surface of the electronic device 100. The support member 172 may be formed of, for example, a metal material and/or a non-metal material (e.g., polymer). In the support member 172, a surface may be coupled to the display 120 and another surface may be coupled to the PCB 174. A processor, memory, and/or an interface may be mounted on the PCB 174. The processor may include, for example, one or more of a central processing unit, an application processor, a graphic processing unit (GPU), an application processor, a sensor processor, or a communication processor.

The memory may include, for example, a volatile memory or a non-volatile memory. The interface may include, for example, a high definition multimedia interface (HDMI), a universal serial bus (USB) interface, an SD card interface, and/or an audio interface. The interface may, for example, electrically or physically connect the electronic device 100 to an external electronic device, and may include a USB connector, an SD card/MMC connector, or an audio connector.

The battery 173 is a device for supplying power to at least one component of the electronic device 100, and may include, for example, a non-rechargeable primary battery, a rechargeable secondary battery, or a fuel cell. At least a portion of the battery 173 may be disposed, for example, on substantially the same plane as the PCB 174. The battery 173 may be integrally disposed inside the electronic device 100, or may be disposed to be detachably attached to the electronic device 100.

The first antenna 171 may be disposed between the display 120 and the support member 172. The first antenna 171 may include, for example, a near field communication (NFC) antenna, a wireless charging antenna, and/or a magnetic secure transmission (MST) antenna. The first antenna 171 may, for example, perform short-range communication with an external device, wirelessly transmit and receive power used for charging, and transmit a magnetic-based signal including a short-range communication signal or payment data. In another embodiment, an antenna structure may be formed by a portion of the frame 110 and/or the support member 172 or a combination thereof. The first antenna 171 has been described as being disposed between the display 120 and the support member 172, but is not limited thereto.

The second antenna 176 may be disposed between the PCB 174 and the rear plate 107. The second antenna 176 may include, for example, a near field communication (NFC) antenna, a wireless charging antenna, and/or a magnetic secure transmission (MST) antenna. The second antenna 176 may, for example, perform short-range communication with an external device, wirelessly transmit and receive power used for charging, and transmit a magnetic-based signal including a short-range communication signal or payment data. In another embodiment, an antenna structure may be formed by a portion of the frame 110 and/or the rear plate 107 or a combination thereof. One of the first antenna 171 and the second antenna 176 may be omitted, and in a case that one antenna is omitted, another antenna may perform a function in place thereof.

The sealing member 175 may be disposed between the frame 110 and the rear plate 107. The sealing member 175 may be configured to block moisture and a foreign substance from entering a space surrounded by the frame 110 and the rear plate 107 from the outside. The electronic device 100 may be referred to as a wearable device in terms of being worn on a part (e.g., a wrist) of the body of the user.

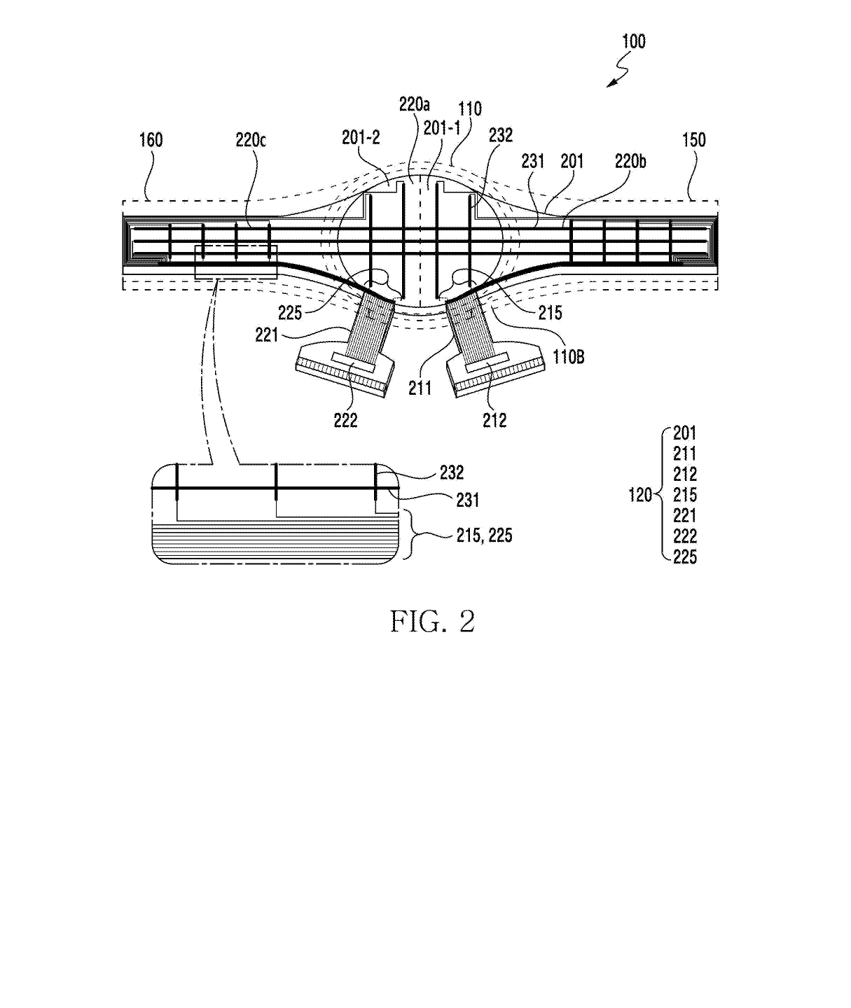

FIG. 2 is a diagram exemplarily representing an exemplary display including a plurality of driving circuitries.

In an electronic device 100, a size of driving circuitry for driving a display extended to an area in which straps are disposed may increase. In the display extended to the area in which the straps are disposed, the number of patterns for a touch sensor and the number of pixels may increase by an increased extent. As the number of patterns for the touch sensor and the number of pixels increase, the size of the driving circuitry may increase. According to the driving circuitry having the increased size, a width of a bending area of a chip on plastic (COP) portion extending from a display panel may increase. The increase in the width of the bending area in a case of being disposed in a frame formed in a circular shape may cause a lack of space for accommodating other electronic components as the driving circuitry is disposed closer to a center portion of the frame. Due to the increase in the bending width, a bezel width of a product may be increased.

Referring to FIG. 2, the electronic device 100 may include a frame 110, a display 120, a first strap 150, and a second strap 160. The electronic device 100 may omit one or more of the above-described components, and may further include another component.

The frame 110 may include metal or polymer, and may have rigidity. The frame 110 may be formed in a circular shape. However, it is not limited thereto, and the frame 110 may be formed in a polygonal shape. For example, the frame 110 may be configured as various polygonal shapes such as a quadrangle, a hexagon, or an octagon. A front surface of the frame 110 facing the display 120 may include a support member (e.g., the support member 172 of FIG. 1C) to support a portion of the display 120. The first strap 150 and the second strap 160 may be extended from a side surface 110B of the frame 110. The first strap 150 may be extended from a portion of the side surface 110B of the frame 110, and the second strap 160 may be extended from a remaining portion of the side surface 110B of the frame 110. For example, the first strap 150 may be extended from the portion of the side surface 110B of the frame 110. The second strap 160 may be extended from another part of the side surface 110B of the frame 110 in a direction opposite to an extension direction of the first strap 150. The first strap 150 and the second strap 160 may be bent to wrap around a part of a body of a user when the electronic device 100 is worn on the part of the body.

The display 120 may be disposed on the front surface of the frame 110, the first strap 150, and the second strap 160. The display 120 may include a first part 220a disposed on the frame 110, a second part 220b disposed on the first strap 150, and a third part 220c disposed on the second strap 160. The first part 220a may maintain a shape of the first part 220a by being disposed on the frame 110 formed of a rigid material. The first part 220a may have rigidity. As the second part 220b and the third part 220c are disposed on the first strap 150 and the second strap 160 formed of a flexible material, a shape of the second part 220b and the third part 220c may be changed. The second part 220b and the third part 220c may have flexibility. The display 120 may be bent to surround a part of the body of the user when the electronic device 100 is worn on the part of the body. The display 120 may be referred to as a flexible display or a bendable display in terms of being bendable to fit the body of the user.

The display 120 may include a display panel 201, a first bending part 211, a second bending part 221, first driving circuitry 212, second driving circuitry 222, first wires 215, and second wires 225. The display 120 may omit one or more of the above-described components and may further include another component.

The display panel 201 may provide visual information to the outside of the electronic device 100. For example, the display panel 201 may transmit visual information to the user through a window of the display 120 disposed to protect the display panel 201. The display 120 may include light emitting elements to provide visual information. The display panel 201 may include light emitting elements forming pixels. A light emitting element may include a light emitting diode (LED), an organic light emitting diode (OLED), a micro LED, or a mini LED.

The first bending part 211 may be formed by extending a portion of a substrate of the display panel 201. The first bending part 211 may be extended from a side of the display panel 201. The first bending part 211 may be bent into a space surrounded by a frame. The second bending part 221 may be formed by extending another portion of the substrate of the display panel 201. The second bending part 221 may be extended from another side of the display panel 201. The second bending part 221 may be bent into the space surrounded by the frame. The first bending part 211 and the second bending part 221 may be a substrate of the display panel 201. The first driving circuitry 212 may be disposed on the substrate of the display panel 201 extending through the first bending part 211. The second driving circuitry 222 may be disposed on the substrate of the display panel 201 extending through the second bending part 221.

The first driving circuitry 212 and the second driving circuitry 222 may be disposed in a space surrounded by a side wall forming the side surface 110B of the frame 110. The first driving circuitry 212 and the second driving circuitry 222 may be disposed on a planar portion having rigidity. The first driving circuitry 212 and the second driving circuitry 222 may be disposed on a support member in the frame 110. The first driving circuitry 212 and the second driving circuitry 222 may be difficult to be disposed on the straps 150 and 160, which are deformed according to whether the user wears the electronic device.

The first driving circuitry 212 and the second driving circuitry 222 may be circuitry configured to control light emitting elements disposed on the display panel 201 to represent a color. The first driving circuitry 212 and the second driving circuitry 222 may control each of specified areas in the display panel 201. For example, the first driving circuitry 212 may be configured to control light emitting elements (or pixels) in a first display area 201-1 of the display panel 201, and the second driving circuitry 222 may be configured to control light emitting elements (or pixels) in a second display area 201-2 of the display panel 201.

The first driving circuitry 212 and the second driving circuitry 222 may be spaced apart from each other. The first bending part 211 and the second bending part 221 may be spaced apart from each other. A panel extending through the first bending part 211 and a panel extending through the second bending part 221 may be disposed so as not to overlap each other in a space surrounded by a side wall of the frame 110.

The first wires 215 may be extended to the first driving circuitry 212 and the first display area 201-1 of the display panel 201. The first wires 215 may be connected to the first driving circuitry 212 and a scan line 231 and a data line 232 in the first display area 201-1 of the display panel 201. The first wires 215 may be extended from the first driving circuitry 212 to the first display area 201-1 of the display panel 201 through the first bending part 211.

The second wires 225 may be extended to the second driving circuitry 222 and the second display area 201-2 of the display panel 201. The second wires 225 may be connected to the second driving circuitry 222 and the scan line 231 and the data line 232 in the second display area 201-2 of the display panel 201. The second wires 225 may be extended from the second driving circuitry 222 to the second display area 201-2 of the display panel 201 through the second bending part 221. An end of the scan line 231 and the data line 232 may be connected to one of wires of the first wires 215 and the second wires 225. Both ends of the scan line 231 and the data line 232 may be connected to the wires.

The scan line 231 may be a line connected to a thin film transistor (TFT) disposed in the display panel 201 to transmit a driving signal from the first driving circuitry 212 or the second driving circuitry 222. The driving signal transmitted by the scan line 231 may be a scan signal capable of turning on a pixel of the display panel 201 through the TFT. The scan line 231 may be proportional to the number of pixels disposed on the display panel 201. The scan line 231 may be referred to as a gate line or a row line.

The data line 232 may be connected to the TFT disposed in the display panel 201 to transmit a driving signal from the first driving circuitry 212 or the second driving circuitry 222. The driving signal transmitted by the data line 232 may be a line that transmits image data for implementing a color of a pixel of the display panel 201. The data line 232 may be referred to as a source line or a column line. The scan line 231 and the data line 232 may intersect each other in a substantially vertical direction. For example, the scan line 231 may be perpendicular with respect to the data line 232.

The number of wires included in the first wires 215 and the second wires 225 may be proportional to the number of pixels of the display panel 201. As the display panel 201 is extended to an area in which the straps 150 and 160 are disposed, the number of pixels may increase. As the number of pixels increases, the data line 232 and the scan line 231 for driving the pixels may increase. As the data line 232 and the scan line 231 for driving the pixels increase, the number of wires included in the first wires 215 and the second wires 225 connected to the data line 232 and the scan line 231 may increase.

In a case that one driving circuitry performs driving of the display panel 201, a size of the driving circuitry increases, and the number of wires extending from the driving circuitry may increase. The increased number of wires may increase a width of a bending part in which the driving circuitry is disposed. The bending part having the increased width may reduce a size of an active area of the display 120 and increase a size of a bezel. In order to reduce the size of the bezel, the electronic device 100 may include the plurality of driving circuitries 212 and 222 and the bending parts 211 and 221 through which wires extending from each of the plurality of driving circuitries 212 and 222 pass.

According to the above-described embodiment, the electronic device 100 may reduce a width of a bent portion of a COP by including the plurality of driving circuitries. As the width of the bent portion decreases, the electronic device 100 may provide a display panel in which the size of the bezel is reduced. The electronic device 100 may maintain the size of the bezel even when the display is expanded.

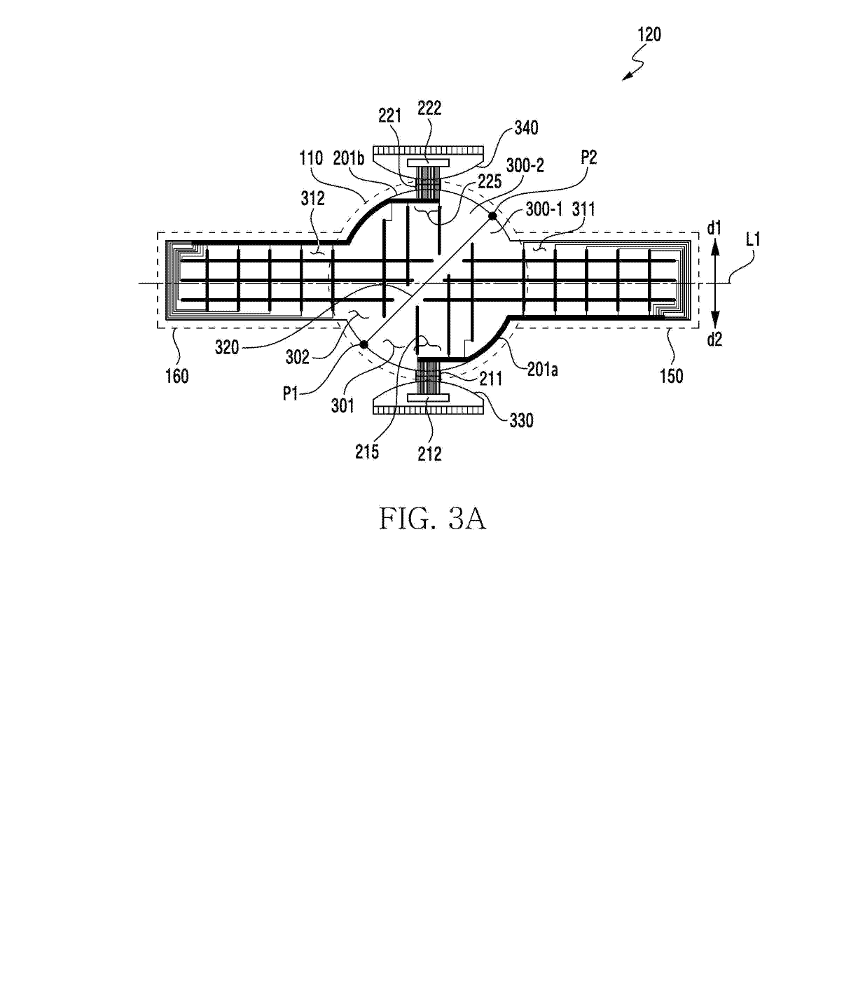

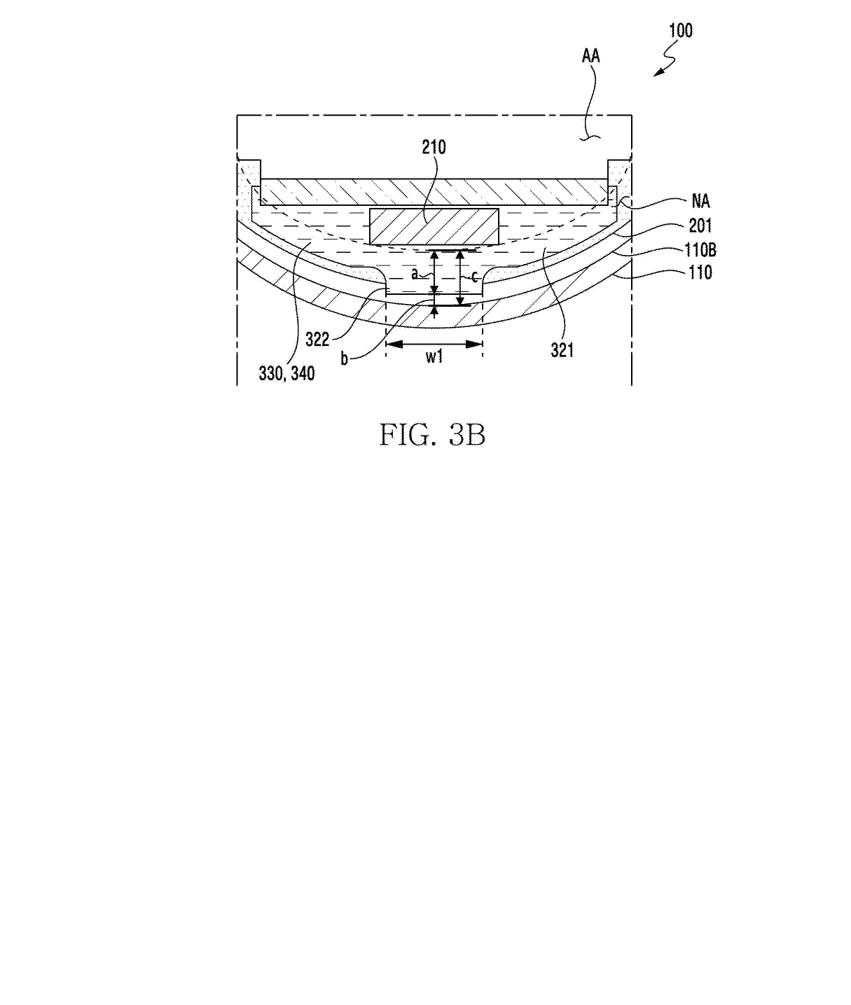

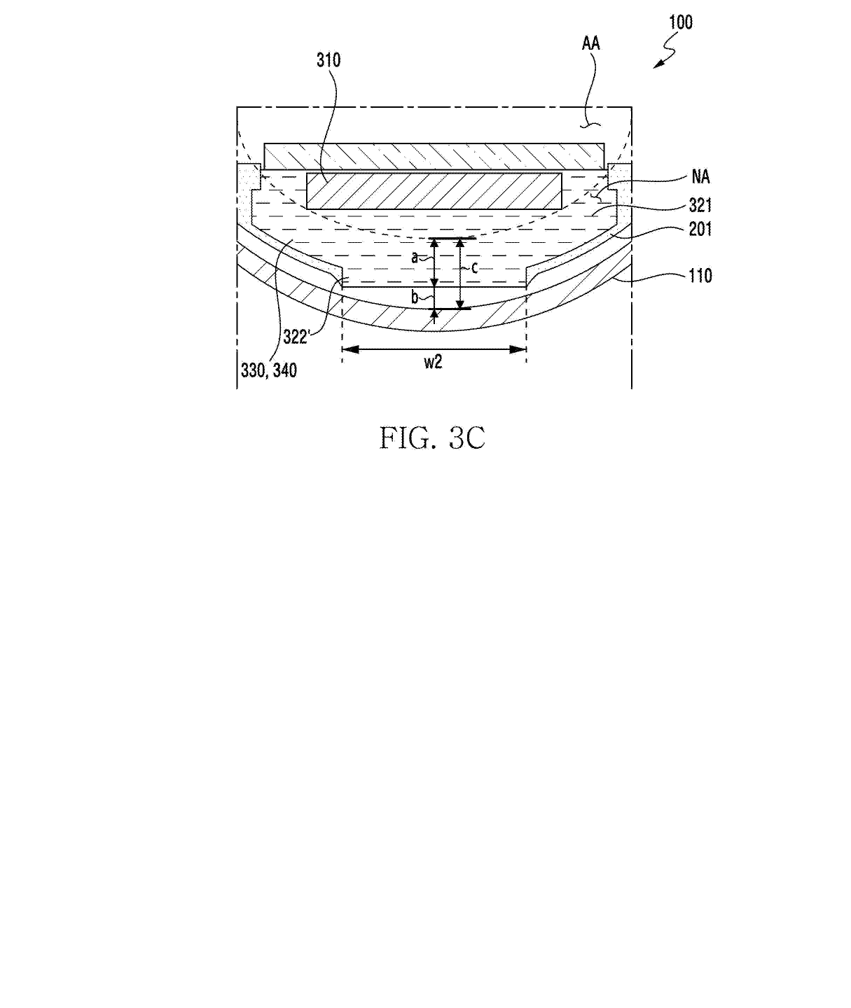

FIG. 3A illustrates an exemplary disposition in which a plurality of exemplary driving circuitries included in a display face each other.

Referring to FIG. 3A, a display 120 may include a first display area 300-1 and a second display area 300-2. The first display area 300-1 may include an area 301 of a display panel 201 and an area 311 of the display panel 201 disposed on a strap (e.g., a first strap 150) connected to the area 301 of the display panel 201. The first display area 300-1 may include the area 301 including a side 201a of the display panel 201 and the area 311 of the display panel 201 on the first strap 150. The side 201a may be disposed on a side surface of a display panel located in a first direction with respect to a virtual line crossing centers of the first strap 150 and a second strap 160. A first bending part 211 may be extended from the side 201a.

The second display area 300-2 may include an area 302 of the display panel 201 and an area 312 of the display panel 201 disposed on a strap (e.g., the second strap 160) connected to the area 302 of the display panel 201. The second display area 300-2 may include the area 302 including another side 201b of the display panel 201 and the area 312 of the display panel 201 on the second strap 160. The another side 201b may be disposed on a side surface of the display panel 201 located in a second directiond2 opposite to the first direction d1 with respect to the virtual line L1 crossing the centers of the first strap 150 and the second strap 160. A second bending part 221 may be extended from the another side 201b.

The first display area 300-1 and the second display area 300-2 may be divided in an area on a frame 110. A boundary 320 between the first display area 300-1 and the second display area 300-2 may be disposed on the frame 110. The boundary 320 between the first display area 300-1 and the second display area 300-2 may be a virtual line connecting a first point p1 between a first substrate 330 extending from the first bending part 211 in which the first driving circuitry 212 is disposed and the second strap 160 and a second point p2 between a second substrate 340 extending from the second bending part 221 in which the second driving circuitry 222 is disposed and the first strap 150. The virtual line may be a line having a straight line, a curved line, or a line having a bent portion. The boundary 320 dividing the first display area 300-1 and the second display area 300-2 may divide a display area of the display panel 201 on the frame in half. For example, the boundary 320 may be a diameter of the frame 110 in a case that the frame 110 has a circular shape. The boundary 320 may be disposed between the first strap 150 and the second strap 160 while being disposed between the first bending part 211 and the second bending part 221.

Wires in the first wires 215 may be extended to the first bending part 211, and may be extended along a side surface of the display panel disposed on a portion of the frame 110 and a side surface of the display panel on the first strap 150, from the first bending part 211. The wires in the first wires 215 may be extended from the first bending part 211 along an edge of the first display area 300-1. For example, a portion of wires in the first wires 215 may be extended from the first bending part 211, along an edge of the another side 201b of the display panel 201, to the second point p2, and a portion of remaining wires in the first wires 215 may be extended along an edge of the another side 201b of the display panel 201 to the display panel 201 on the first strap 150. A portion of the remaining wires in the first wires 215 extending to the second point p2 may be extended to the first point p1 along an edge of the first strap 150.

Each of the wires in the first wires 215 may be connected to one of scan lines 231 and data lines 232 extending from pixels disposed in the first display area 300-1 of the display panel 201.

Wires in the second wires 225 may be extended to the second bending part 221 and may be extended along a side surface of the display panel 201 disposed on a portion of the frame 110 and a side surface of the display panel on the second strap 160, from the second bending part 221. The wires in the second wires 225 may be extended from the second bending part 221 along an edge of the second display area 300-2. For example, a portion of wires in the second wires 225 may be extended from the second bending part 221, along an edge of the side 201a of the display panel 201, to the first point p1, and a portion of remaining wires in the second wires 225 may be extended along an edge of the side 201a of the display panel 201 to the display panel 201 on the second strap 160. A portion of the remaining wires in the second wires 225 may be extended to the second point p2 along an edge of the second strap 160.

Each of the wires in the second wires 225 may be connected to one of the scan lines 231 and the data lines 232 extending from pixels disposed in the second display area 300-2 of the display panel 201.

FIG. 3B represents a disposition of an exemplary bending part of a display including a plurality of driving circuitries. FIG. 3C represents a disposition of an exemplary bending part of a display including one driving circuitry.

Referring to FIGS. 3B and 3C, driving circuitry 210 or 310 may be disposed on a curved substrate 321 extending from a display panel 201 disposed in a frame 110 of an electronic device 100. The driving circuitry 210 of FIG. 3B may be one driving circuitry among two driving circuitries 212 and 222, such as the display 120 of FIG. 3A. The driving circuitry 310 of FIG. 3C may be one driving circuitry disposed in the frame 110 different from the display 120 of FIG. 3A. The driving circuitry 310 may be configured to control both a first display area 300-1 and a second display area 300-2 of the display 120.

The driving circuitry 310 configured to drive pixels in an entire display area of the display 120 may be larger than the driving circuitry 210 configured to drive one display area among the first display area 300-1 or the second display area 300-2. The number of wires connected to the driving circuitry 310 configured to drive the pixels in the entire display area of the display 120 may be greater than the number of wires connected to the driving circuitry 210 configured to drive one display area among the first display area 300-1 or the second display area 300-2. As the number of wires increases, a width of a bending part may increase. A width w1 of a bending part 322 of FIG. 3B may be narrower than a width w2 of a bending part 322′ of FIG. 3C. When the number of wires connected to the driving circuitry 210 of FIG. 3B is half of the number of wires connected to the driving circuitry 310 of FIG. 3C, the width of the bending part 322 may be about half of the width of the bending part 322′. In a case that the display 120 includes two bending parts in which two driving circuitries are disposed respectively, a width of each of bending parts may be the same. For example, a width of a first bending part (e.g., the first bending part 211 of FIG. 2) and a width of a second bending part (e.g., the second bending part 221 of FIG. 2) may be the same as each other.

Pixels may be spaced apart from the bending part 322 or 322′ by a predetermined distance a or more. Pixels may be disposed in an active area AA. An area between the active area AA of the display panel 201 and a side wall 110B of the frame 110 may be an inactive area NA. The inactive area NA may be referred to as a bezel area in terms of being disposed along a display area of the display panel 201 or an edge of the active area AA.

A width c of the inactive area NA may be a sum of the predetermined distance a and a farther distance b among distances between the bending parts 322 or 322’ and the side wall 110B of the frame 110. As the width of the bending part 322 or 322’ increases, the farther distance b among the distances between the bending part 322 or 322’ and the side wall 110B of the frame 110 increases, so the width of the inactive area NA or a width of a bezel may increase.

The electronic device 100 of FIG. 3A or 3B described above may reduce a number of wires passing through the bending part 322 by including the plurality of driving circuitries 212 and 222. The electronic device 100 including the plurality of driving circuitries 212 and 222 may reduce the width of the bezel or the width of the inactive area NA of the display 120 by reducing the width of the bending part 322. Electrical components such as a battery may be disposed between the first driving circuitry 212 and the second driving circuitry 222. The battery may be spaced apart from the first substrate 330 or the second substrate 340 extending through the first bending part 211 and the second bending part 221. In a case that the first bending part 211 and the second bending part 221 are disposed to face each other, a mounting space of electric components such as a battery or a printed circuit board may increase. The electronic device may improve space efficiency by including a plurality of bending parts and a plurality of driving circuitries.

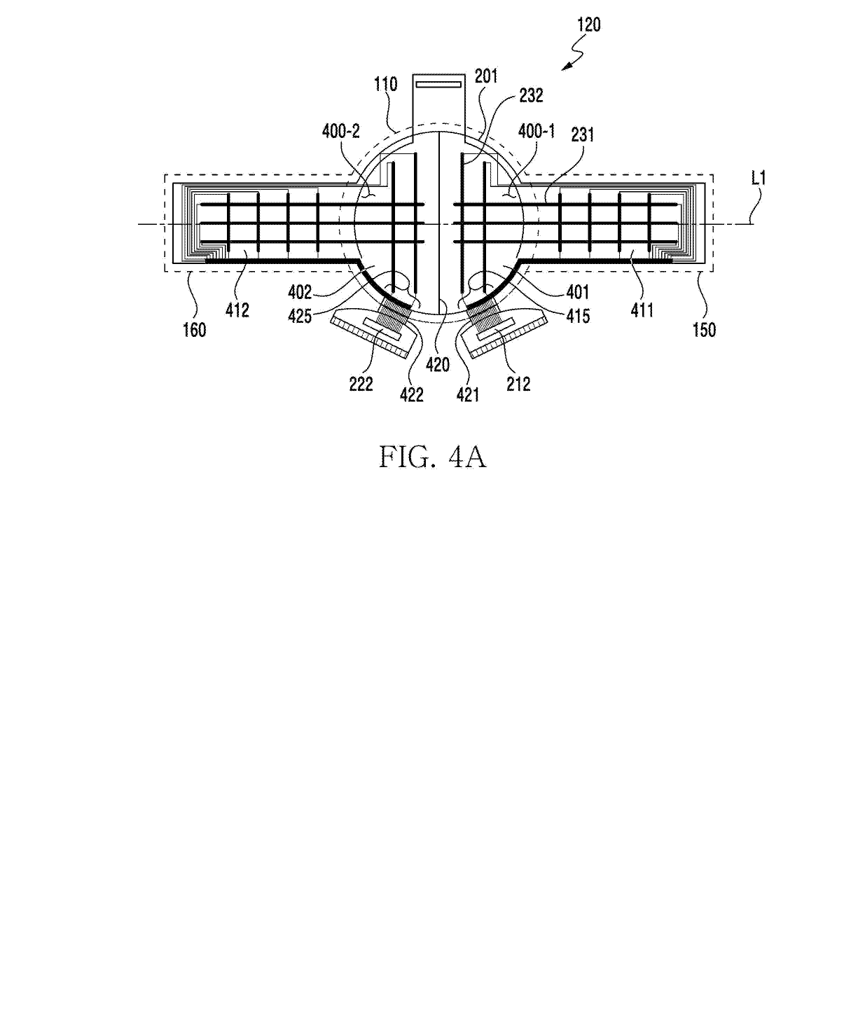

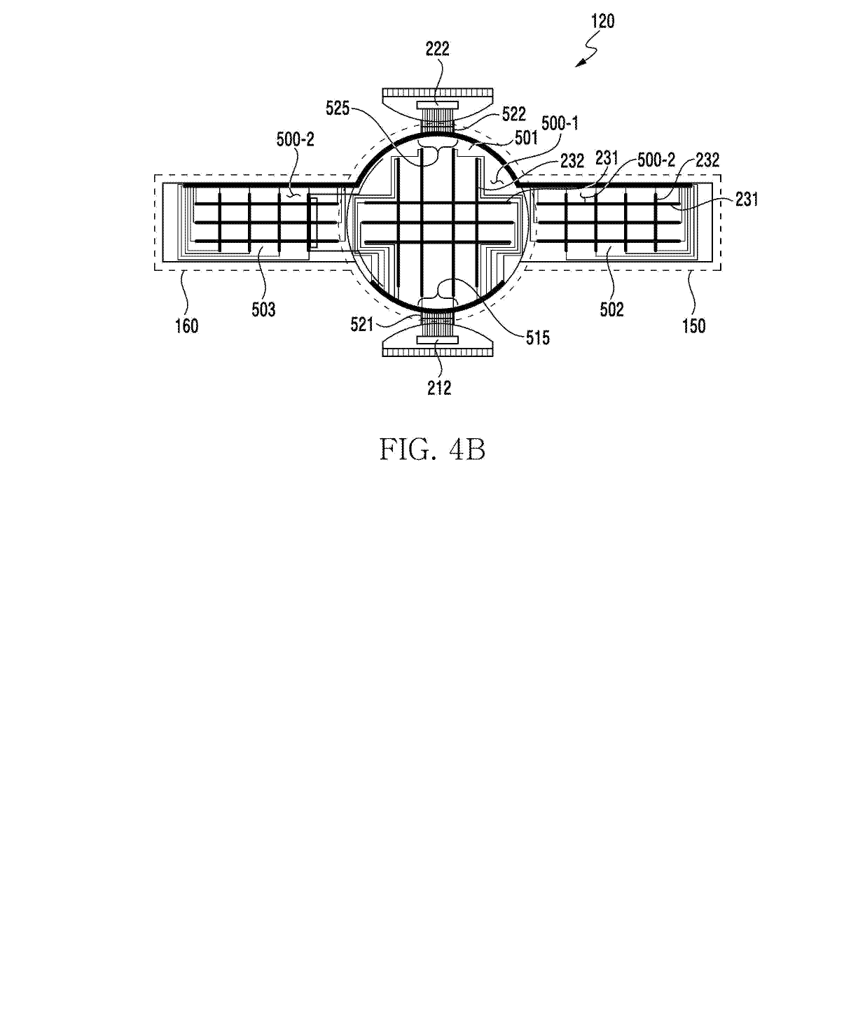

FIG. 4A represents an example in which each of a plurality of exemplary driving circuitries included in a display is disposed next to each other.

Referring to FIG. 4A, a display 120 may include a first display area 400-1 and a second display area 400-2. The first display area 400-1 may include an area 401 of a display panel 201 and an area 411 of the display panel 201 disposed on a strap (e.g., a first strap 150) connected to the area 401 of the display panel 201. The first display area 400-1 may include the area 401 connected to first driving circuitry 212 of the display panel 201 and the area 411 of the display panel 201 on the first strap 150. The area 401 connected to the first driving circuitry 212 may be an area that is perpendicular to the first strap 150 and a second strap 160 and is in contact with the first strap 150 with respect to a virtual line L1 passing through a center of a frame 110.

The second display area 400-2 may include an area 402 of the display panel 201 and an area 412 of the display panel 201 disposed on a strap (e.g., the second strap 160) connected to the area 402 of the display panel 201. The second display area 400-2 may include the area 402 connected to second driving circuitry 222 of the display panel 201 and the area 412 of the display panel 201 on the second strap 160. The area 402 connected to the second driving circuitry 222 may be an area that is perpendicular to the first strap 150 and the second strap 160 and is in contact with the second strap 160 with respect to a virtual line passing through the center of the frame 110.

A first bending part 421 may be formed by extending a portion of a substrate of the display panel 201. The first bending part 421 may be extended from a side surface of the display panel 201. The first bending part 421 may be bent into a space surrounded by the frame 110. A second bending part 422 may be formed by extending another portion of the substrate of the display panel 201. The second bending part 422 may be extended from a side surface of the display panel 201. The second bending part 422 may be bent into the space surrounded by the frame. The first bending part 421 and the second bending part 422 may be disposed on a side surface 110B of the frame 110 facing in the same direction with respect to a virtual line crossing centers of the first strap 150 and the second strap 160.

The first display area 400-1 and the second display area 400-2 may be divided in an area on the frame 110. A boundary 420 between the first display area 400-1 and the second display area 400-2 may be disposed on the frame 110. The boundary 420 between the first display area 400-1 and the second display area 400-2 may be disposed between the first bending part 421 in which the first driving circuitry 212 is disposed and the second bending part 422 in which the second driving circuitry 222 is disposed. The boundary 420 may be disposed between the first strap 150 and the second strap 160. For example, the boundary 420 may be a virtual line perpendicular to the first strap 150 and the second strap 160 and passing through the center of the frame 110. The boundary 420 dividing the first display area 400-1 and the second display area 400-2 may divide a display area of the display panel 201 on the frame in half. For example, the boundary 420 may be a diameter of the frame 110 in a case that the frame 110 has a circular shape. The boundary 420 may be disposed between the first strap 150 and the second strap 160 while being disposed between the first bending part 421 and the second bending part 422.

Wires in a set of first wires 415 may be extended along a side surface of the display panel 201 disposed on a portion of the frame 110 and a side surface of the display panel 201 on the first strap 150, through the first bending part 421. The wires in the set of the first wires 415 may be extended from the first bending part 421 along an edge of the first display area 400-1. For example, a portion of the wires in the set of the first wires 415 may be extended from the first bending part 421, along a side surface of the display panel 201, to the first strap 150. The portion of the wires in the set of the first wires 415 extending to the first strap 150 may be extended along an edge of the first strap 150 to the boundary 420 between the first display area 400-1 and the second display area 400-2. Other wires in the set of the first wires 415 may be extended from the first bending part 421, along a side surface of the display panel 201, to the boundary 420 disposed between the first driving circuitry 212 and the second driving circuitry 222. Each of the wires in the set of the first wires 415 may be connected to one of scan lines 231 and data lines 232 extending from pixels disposed in the first display area 400-1 of the display panel 201.

Wires in a set of second wires 425 may be extended along a side surface of the display panel 201 disposed on a portion of the frame 110 and a side surface of the display panel 201 on the second strap 160, through the second bending part 422. The wires in the set of the second wires 425 may be extended from the second bending part 422 along an edge of the second display area 400-2. For example, a portion of the wires in the set of the second wires 425 may be extended from the second bending part 422, along a side surface of the display panel 201, to the second strap 160. The portion of the wires in the set of the second wires 425 extending to the second strap 160 may be extended along an edge of the second strap 160 to the boundary 420 between the first display area 400-1 and the second display area 400-2. Other wires in the set of the second wires 425 may be extended from the second bending part 422, along a side surface of the display panel 201, to the boundary 420 disposed between the first driving circuitry 212 and the second driving circuitry 222. Each of the wires in the set of the second wires 425 may be connected to one of scan lines 231 and data lines 232 extending from pixels disposed in the second display area 400-2 of the display panel 201.

The first strap 150 may be closer to the first bending part 421 among the first bending part 421 and the second bending part 422. The second strap 160 may be closer to the second bending part 422 among the first bending part 421 and the second bending part 422.

FIG. 4B exemplarily represents display areas controlled by each of a plurality of exemplary driving circuitries included in a display.

Referring to FIG. 4B, a display 120 may include a first display area 500-1 and a second display area 500-2. The first display area 500-1 may include an area 501 among display areas of a display panel 201. The area 501 may be an area corresponding to a frame 110.

The second display area 500-2 may include areas 502 and 503 among display areas of the display panel 201 corresponding to a first strap 150 and a second strap 160.

A first bending part 521 may be formed by extending a portion of a substrate of the display panel 201. The first bending part 521 may be extended from a side surface of the display panel 201. The first bending part 521 may be bent into a space surrounded by the frame 110. A second bending part 522 may be formed by extending another portion of the substrate of the display panel 201. The second bending part 522 may be extended from a side surface of the display panel 201. The second bending part 522 may be bent into the space surrounded by the frame. The first bending part 521 and the second bending part 522 may be disposed on a side surface 110B of the frame 110 facing in a different direction with respect to a virtual line crossing centers of the first strap 150 and the second strap 160. However, it is not limited thereto, and as illustrated in FIG. 4A, the first bending part 521 and the second bending part 522 may be disposed on the side surface 110B of the frame 110 facing the same direction with respect to the virtual line crossing the centers of the first strap 150 and the second strap 160.

Wires in a set of first wires 515 may be extended from first driving circuitry 212 to the first bending part 521. The wires in the set of the first wires 515 may be extended along the side surface 110B of the frame 110 through the first bending part 521. The wires in the set of the first wires 515 may be extended from the first bending part 521 along an edge of the first display area 500-1. For example, the wires in the set of the first wires 515 may be extended along the side surface 110B of the frame 110. Each of the wires in the set of the first wires 515 may be connected to one of scan lines 231 and data lines 232 extending from pixels disposed in the first display area 500-1 of the display panel 201.

Wires in a set of second wires 525 may be extended from second driving circuitry 222 to the second bending part 522. The wires in the set of the second wires 525 may be extended along a side surface of the display panel 201 on the first strap 150 and the second strap 160 through the second bending part 522. Each of the wires in the set of the second wires 525 may be connected to one of the scan lines 231 and the data lines 232 extending from pixels disposed in the second display area 500-2 of the display panel 201.

The first display area 500-1 and the second display area 500-2 of the display panel 201 may be controlled, respectively. For example, the second display area 500-2 corresponding to a strap may display an image different from a display image of the first display area 500-1. For example, the display 120 may provide a watch face through the first display area 500-1 and an image of a strap through the second display area 500-2. The image of the strap may be an image indicating a material (fiber, woven fabric, leather, and silicone) of the strap. The strap image may include a sticker or an icon decorating the strap.

According to an embodiment, the second driving circuitry 222 may be configured to inactivate the second display area 500-2 while the first display area 500-1 is activated through the first driving circuitry 212. While the watch face is displayed in the first display area 500-1 through the first driving circuitry 212, the second driving circuitry 222 may be configured to be turned off. While the watch face is displayed in the first display area 500-1 through the first driving circuitry 212, the second driving circuitry 222 may be configured to display a black image in the second display area 500-2.

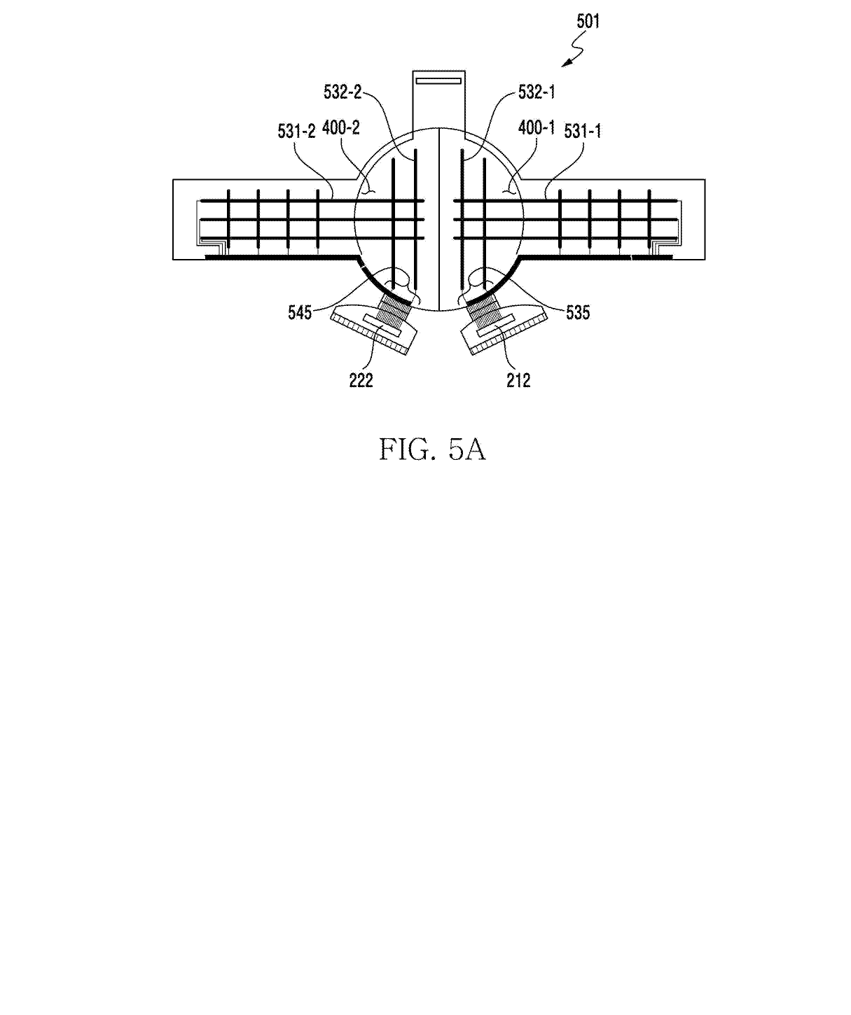

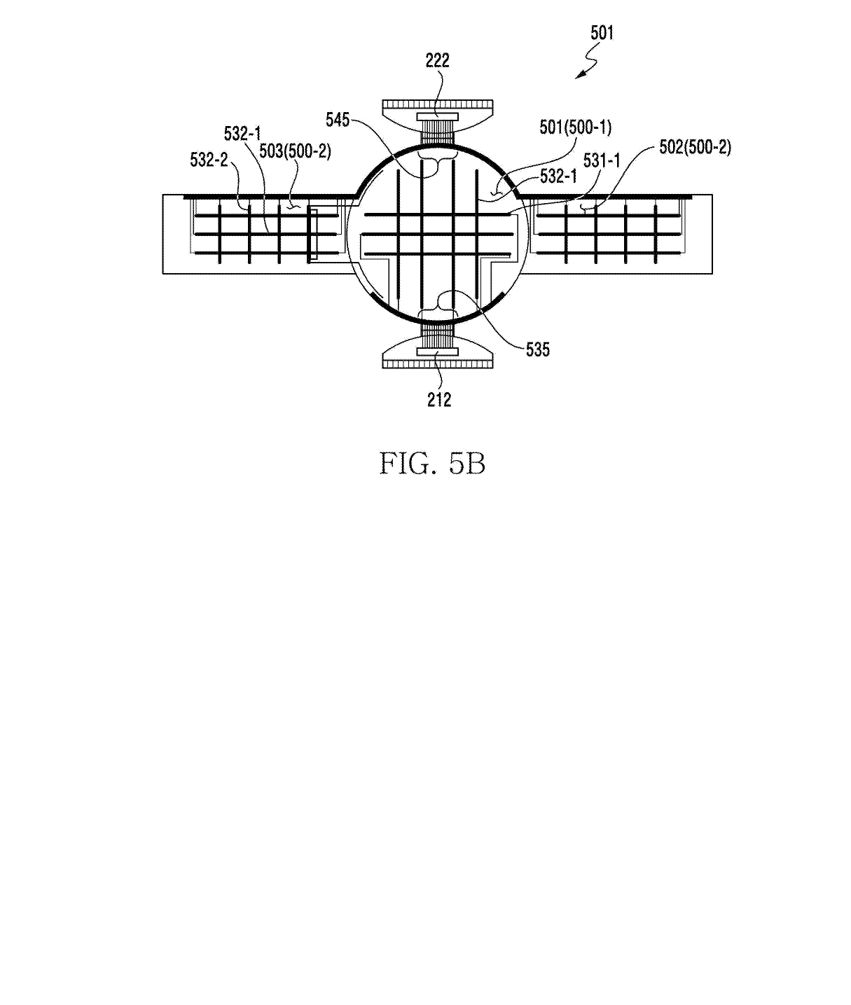

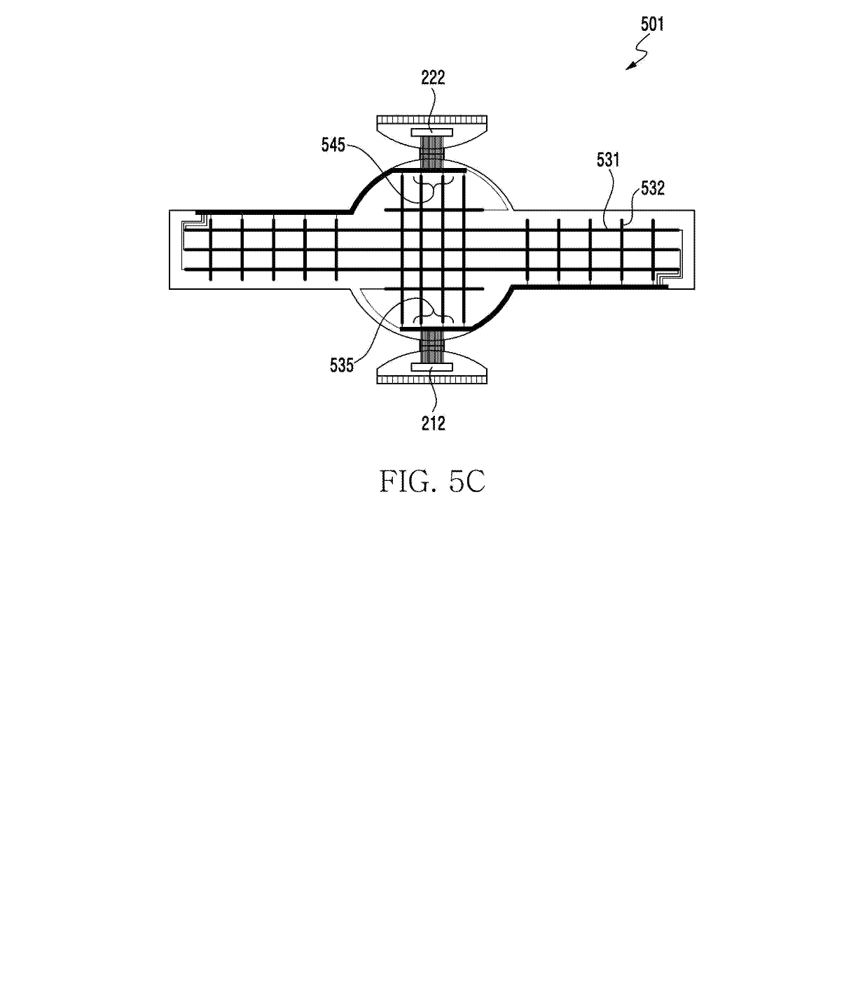

FIGS. 5A, 5B, and 5C exemplarily represent touch patterns connected to a plurality of driving circuitries.

Referring to FIGS. 5A, 5B, and 5C a display (e.g., the display 120 of FIGS. 2, 3A, 3B, 3C, 4A, or 4B) of an electronic device (e.g., the electronic device 100 of FIG. 2) may further include a touch layer 501. The touch layer 501 may be one of layers configuring the display 120. For example, the touch layer 501 may be disposed on a display panel (e.g., the display panel 201 of FIGS. 2, 3A, 3B, 3C, 4A, or 4B.

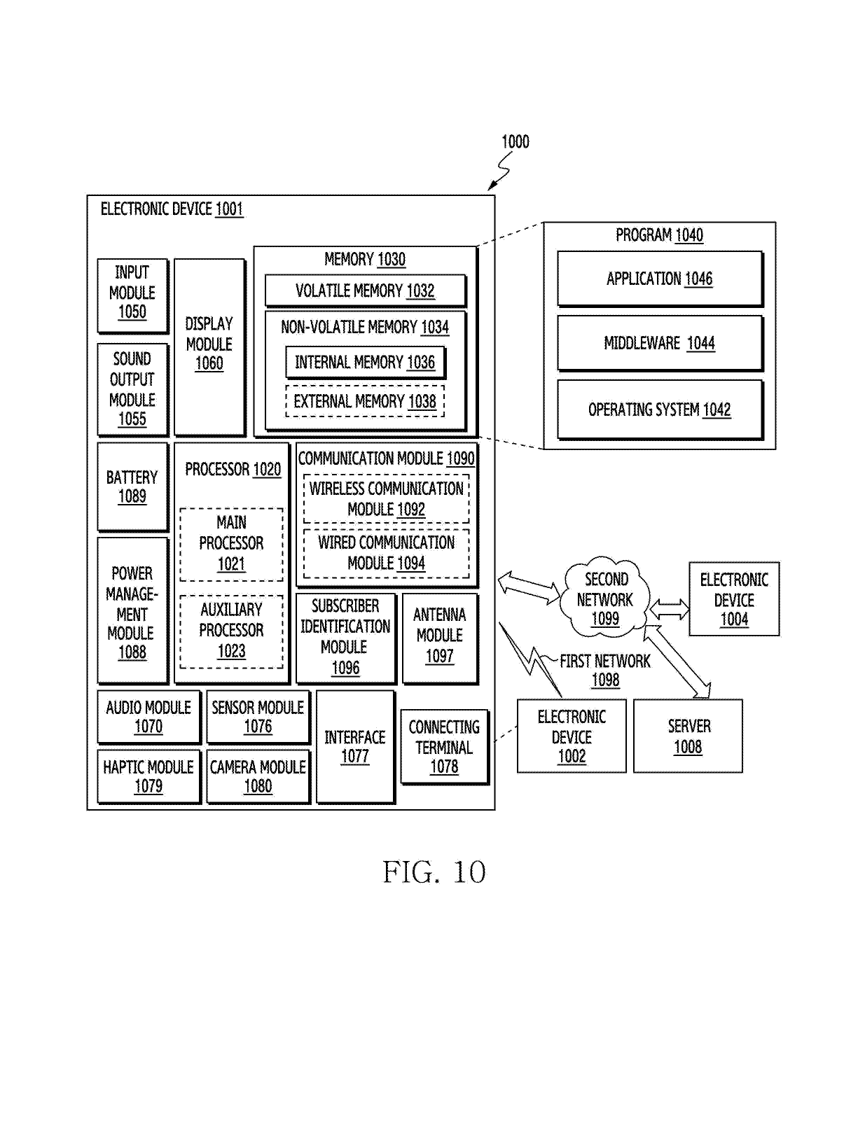

The touch layer 501 may include a plurality of conductive lines 531, 532, 531-1, 532-1, 531-2, and 532-2. In a case that an external object is in contact with a display area (e.g., the display area 400-1, 400-2, 500-1, or 500-2 of FIGS. 4A or 4B) through the touch layer 501, the electronic device 100 or a processor (e.g., a processor 1020 of FIG. 10) of the electronic device 100 may be configured to obtain a change in capacitance between the plurality of conductive lines 531, 532, 531-1, 532-1, 531-2, and 532-2. The processor 1020 may be configured to identify a contact point between the external object and the display area based on the change in the capacitance. The processor 1020 may be configured to obtain an input based on the identified contact point. A portion of wires among a plurality of conductive lines may be disposed in parallel, and another portion of the wires may be disposed perpendicular to the portion of the wires. A voltage applied to the portion of the wires and a voltage applied to another portion of the wires may be different. The capacitance may be capacitance between the portion of the wires and another portion of the wires.

Referring to FIG. 5A, the touch layer 501 may include the plurality of conductive lines 531-1, 532-1, 531-2,and 532-2 to correspond to the display areas 400-1 and 400-2 of FIG. 4A. The touch layer 501 may include the first conductive lines 531-1 and the third conductive lines 531-2 extending in a first direction (e.g., a horizontal direction in the drawing), and the second conductive lines 532-1 and the fourth conductive lines 532-2 extending in a second direction perpendicular to the first direction. The first conductive lines 531-1 and the third conductive lines 532-1 may intersect with the second conductive lines 531-2 and the fourth conductive lines 532-2.

First wires 535 extending from first driving circuitry 212 may be connected to the first and second conductive lines 531-1 and 532-1 disposed in a portion corresponding to the first display area 400-1. The first wires 535 may be connected to one end among ends of each of the first and second conductive lines 531-1 and 532-1. In the first wires 535, one end of both ends of the first and second conductive lines 531-1 and 532-1 may be connected to one wire among the first wires 535.

Second wires 545 extending from second driving circuitry 222 may be connected to the third and fourth conductive lines 531-2 and 532-2 disposed in a portion corresponding to the second display area 400-2. The second wires 545 may be connected to one end among ends of each of the third and fourth conductive lines 531-2 and 532-2. In the second wires 545, one end of both ends of the third and fourth conductive lines 531-2 and 532-2 may be connected to one wire among the first wires 545.

Referring to FIG. 5B, the touch layer 501 may include the plurality of conductive lines 531-1, 532-1, 531-2, and 532-2 to correspond to the display areas 500-1 and 500-2 of FIG. 4B. The touch layer 501 may include the first conductive lines 531-1 and third conductive lines 531-2 extending in the first direction (e.g., the horizontal direction in the drawing), and the second conductive lines 532-1 and the fourth conductive lines 532-2 extending in the second direction perpendicular to the first direction. The first display area 500-1 may be a display area of the display corresponding to a frame, and the second display area 500-2 may be a display area of the display corresponding to a strap. The first display area 500-1 may include an area 501 on the frame, and the second display area 500-2 may include spaced-apart areas 502 and 503. The first conductive lines 531-1 and the second conductive lines 532-1 may be disposed in an area of the touch layer 501 corresponding to the first display area 500-1. The third conductive lines 531-2 and the fourth conductive lines 532-2 may be disposed in an area of the touch layer 501 corresponding to the second display area 500-2.

The first wires 535 extending from the first driving circuitry 212 may be connected to the first and second conductive lines 531-1 and 532-1 disposed in a portion corresponding to the first display area 400-1. The first wires 535 may be connected to one end among ends of each of the first and second conductive lines 531-1 and 532-1. One end of both ends of the first and second conductive lines 531-1 and 532-1 may be connected to one wire among the first wires 535.

The second wires 545 extending from the second driving circuitry 222 may be connected to the third and fourth conductive lines 531-2 and 532-2 disposed in a portion corresponding to the second display area 400-2. The second wires 545 may be connected to one end among ends of each of the third and fourth conductive lines 531-2 and 532-2. One end of both ends of the third and fourth conductive lines 531-2 and 532-2 may be connected to one wire among the first wires 545.

Referring to FIG. 5C, regardless of a display area, the touch layer 501 may include the conductive lines 531 and 532 that intersect each other. The conductive lines 531 and 532 may be disposed in an area corresponding to the entire display areas 400-1, 400-2, 500-1, and 500-2. The first conductive lines 531 may be extended in a first direction, and the second conductive lines 532 may be extended in a second direction perpendicular to the first direction. In the touch layer 501, the first wires 535 extending from the first driving circuitry 212 and the second wires 545 extending from the second driving circuitry 222 may be connected to the conductive lines 531 and 532. The first wires 535 extending from the first driving circuitry 212 and the second wires 545 extending from the second driving circuitry 222 may be connected to one end among ends of each of the conductive lines 531 and 532. The conductive wires of the touch layer 501 may be extended along an edge of a frame (e.g., the frame 110 of FIG. 1C) and straps (e.g., the straps 150 and 160 of FIG. 1C).

The wires in the touch layer 501 of FIGS. 5A, 5B, and 5C described above may be disposed to correspond to the display area 400-1, 400-2, 500-1, or 500-2, but may be disposed regardless of the display area. For example, each of the touch layer 501 of FIG. 5A, the touch layer 501 of FIG. 5B, or the touch layer 501 of FIG. 5C may be applied to all of the display 120 of FIG. 3A, the display 120 of FIG. 4A, or the display 120 of FIG. 4B.

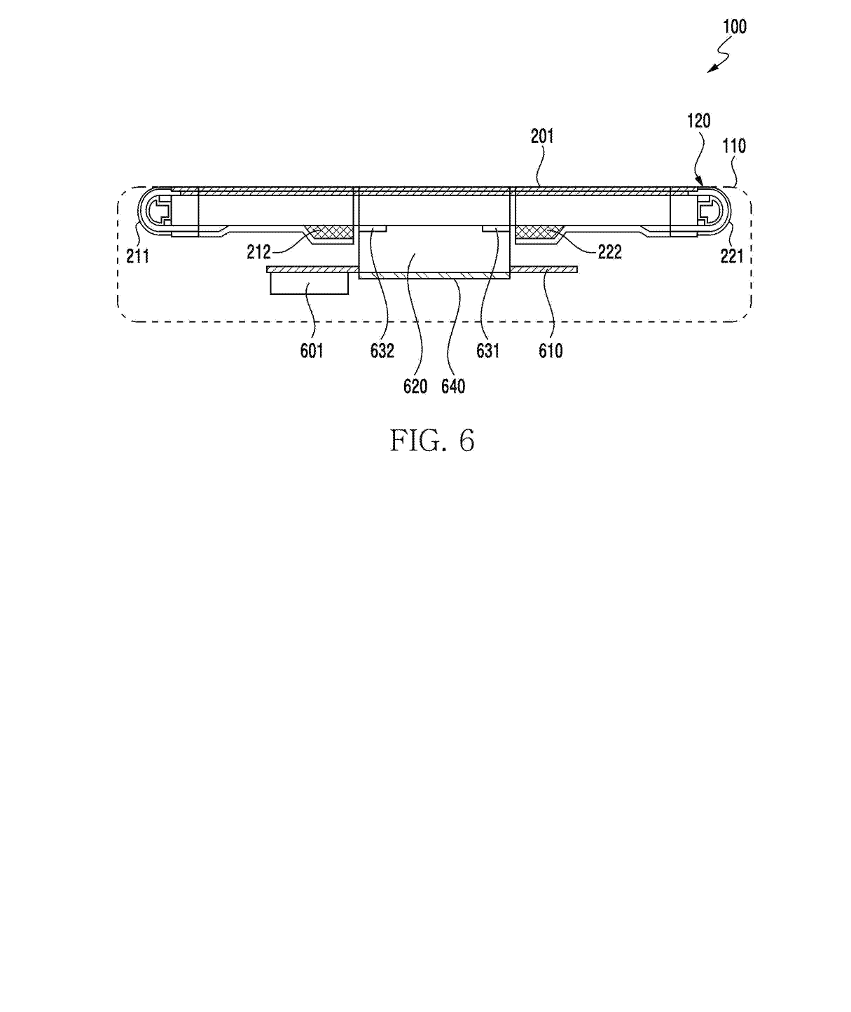

FIG. 6 is a diagram representing a connection structure between a bending part of a display panel and a printed circuit board.

Referring to FIG. 6, a display 120 of an electronic device 100 may include a display panel 201 including light emitting elements, a first bending part 211, first driving circuitry 212, a second bending part 221, second driving circuitry 222, at least one processor 601, a printed circuit board 610, and a flexible printed circuit board 620. The display 120 may omit one or more of the above-described components and may further include another component.

The display panel 201 may include a light emitting element to provide visual information to the outside of the electronic device 100. The display 120 may further include a window (not illustrated) to protect the outside of the display panel 201. The window may be disposed on a layer including a light emitting element. The light emitting element may include an LED, an OLED, a micro LED, or a mini LED. The window may be formed of glass or a polymer material. The window may include ultra thin glass (UTG) or a polymer material (e.g., polyimide (PI), polycarbonate (PC), or polyethylene (PET)).

The first bending part 211 may be formed by extending a portion of a substrate of the display panel 201. The first bending part 211 may be extended from a side of the display panel 201. The first bending part 211 may be bent into a space surrounded by a frame. The second bending part 221 may be formed by extending another portion of the substrate of the display panel 201. The second bending part 221 may be extended from another side of the display panel 201. The second bending part 221 may be bent into the space surrounded by the frame.

The first bending part 211 and the second bending part 221 may be a portion of the substrate of the display panel 201. The substrate may be formed of a polymer material. The substrate may include a polymer material (e.g., PI) having flexibility. The substrate formed of the flexible material may be disposed on a rear surface of the display panel 201 by being bent through the first bending part 211 and the second bending part 221.

The first driving circuitry 212 and the second driving circuitry 222 may be disposed on a planar portion. The first driving circuitry 212 and the second driving circuitry 222 may be disposed in a portion disposed on the frame 110 in which a shape of the display panel 201 is maintained.

The first driving circuitry 212 and the second driving circuitry 222 may control to represent a color of pixels formed of light emitting elements. The first driving circuitry 212 and the second driving circuitry 222 may receive image information displayed on the display panel 201 through the processor 601. The first driving circuitry 212 and the second driving circuitry 222 may be connected to the processor 601 through the flexible printed circuit board 620.

The flexible printed circuit board 620 may be attached to a substrate on which the first driving circuitry 212 and the second driving circuitry 222 are disposed. The display 120 may further include a first bonding portion 631 disposed on a substrate extending through the first bending part 211 and a second bonding portion 632 disposed on a substrate extending through the second bending part 221. For example, the flexible printed circuit board 620 may be disposed on a surface of a panel on which the first driving circuitry 212 and the second driving circuitry 222 are disposed. Bonding portions of the flexible printed circuit board 620 may be plural. For example, the first bonding portion 631 of the flexible printed circuit board 620 may be disposed next to the first driving circuitry 212, and the second bonding portion 632 of the flexible printed circuit board 620 may be disposed next to the second driving circuitry 212. The first bonding portion 631 and the second bonding portion 632 of the flexible printed circuit board 620 may be attached to the substrate. The first bonding portion 631 and the second bonding portion 632 may be thermally compressed to the substrate. The first bending part 211 and the second bending part 221 may be connected to the flexible printed circuit board 620 through the first bonding portion 631 and the second bonding portion 632. The flexible printed circuit board 620 may be connected to the printed circuit board 610. The flexible printed circuit board 620 may be connected to the printed circuit board 610 through a connection member (e.g., a connector) 640. The at least one processor 601 disposed on the printed circuit board 610 through the flexible printed circuit board 620, the first driving circuitry 212, and the second driving circuitry 222 may be electrically connected.

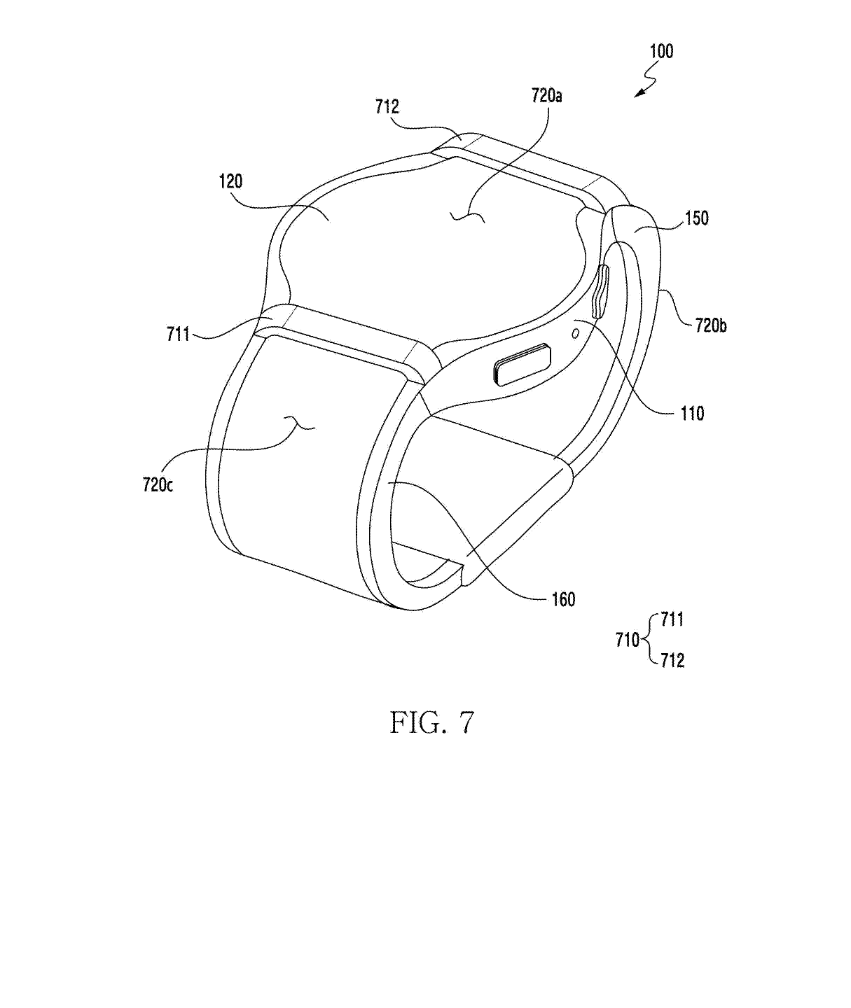

FIG. 7 represents an exemplary structure included in a frame to visually separate a display area.

Referring to FIG. 7, an electronic device 100 may include a frame 110, a display 120, a first strap 150, and a second strap 160. The display 120, the first strap 150, and the second strap 160 may be similar to the configurations described in FIGS. 1A, 1B, and 1C and descriptions of overlapping portions are omitted.

The display 120 may be disposed on the frame 110, the first strap 150, and the second strap 160. The frame 110 may include a partition wall 710 that divides a display area of the display 120.

A first partition wall 711 may be disposed between a first display area 720a of the display 120 disposed on the frame 110 and a second display area 720b of the display 120 disposed on the first strap 150. The first partition wall 711 may protrude from an edge of the frame 110 in contact with the first strap 150 to a front surface of the electronic device 100. A second partition wall 712 may be disposed between the first display area 720a of the display 120 disposed on the frame 110 and a third display area 720c of the display 120 disposed on the second strap 160. The second partition wall 712 may protrude from an edge of the frame 110 in contact with the second strap 160 to the front surface of the electronic device 100.

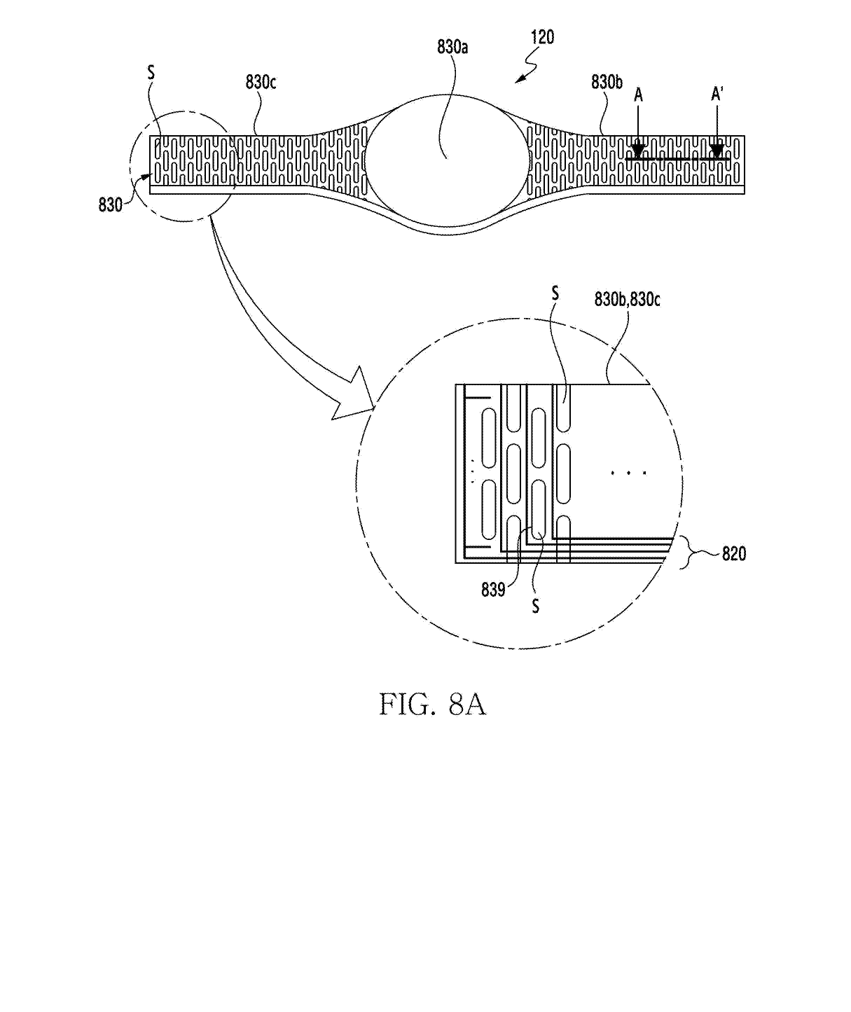

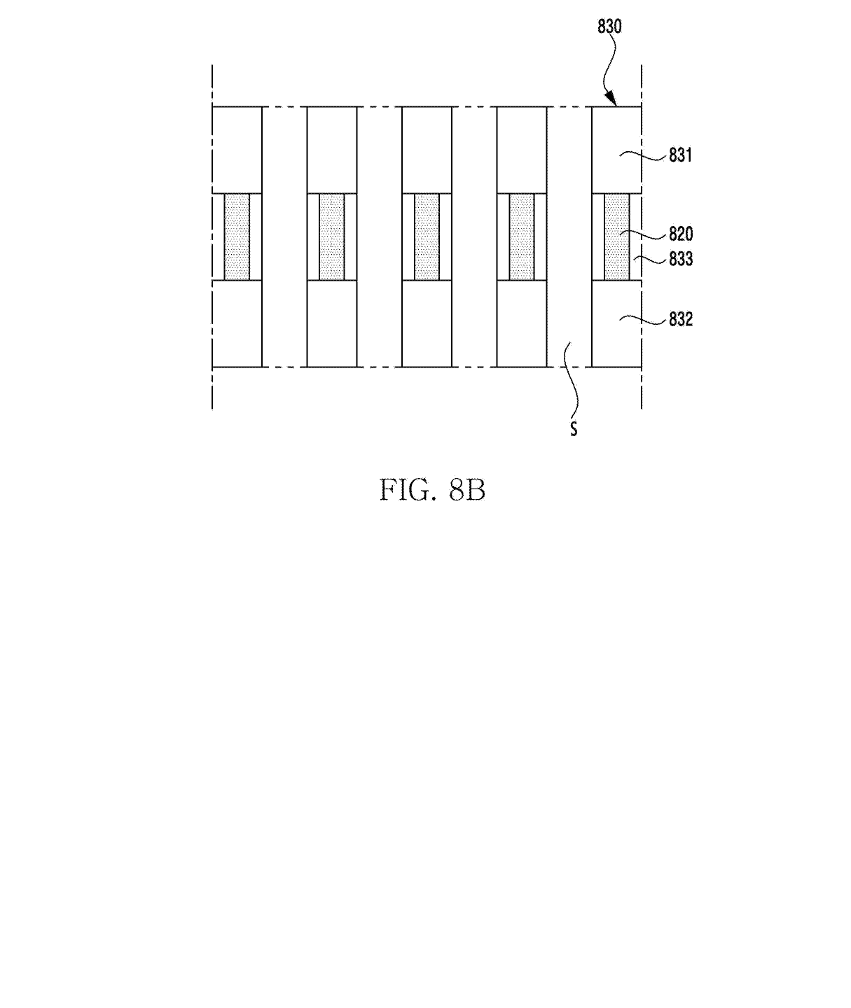

FIG. 8A represents a support plate disposed below a display panel and configured to bend a strap. FIG. 8B represents a cross-section of a support plate.

Referring to FIGS. 8A and 8B, a support plate 830 disposed on a rear surface 120b of a display 120 may include a planar part 830a and pattern parts 830b and 830c. The support plate 830 may support a layer on which light emitting elements are disposed. The support plate 830 may include the planar part 830a disposed on a frame 110, the first pattern part 830b, disposed on a first strap 150, including a plurality of slits S, and the second pattern part 830c, disposed on a second strap 160, including the plurality of slits S. The planar part 830a is illustrated as not having a pattern including the slits S but is not limited thereto. The planar part 830a may include slits in at least a partial area. A width of the slits included in the planar part 830a and a gap between the slits may be different from a width of the slits S of the pattern parts 830b and 830c and a gap between the slits S.

Referring to FIG. 8B in which an area including the pattern parts 830b and 830c is cut along line A-A’, the support plate 830 configuring the display 120 may include a plurality of layers. The plurality of layers may include outer layers 831 and 832 forming an outer surface of the support plate 830 and a conductive layer 833 including conductive patterns 820. The outer layers 831 and 832 may be formed of a material having rigidity to support a light emitting layer of the display 120. For example, the outer layers 831 and 832 may include a polymer compound of a composite material such as CFRP, GFRP, BFRP, or AFRP. However, it is not limited thereto, and the outer layers 831 and 832 may include a metal material. The outer layers 831 and 832 may include the plurality of slits S in the pattern parts 830b and 830c such that the display 120 bends along a part of a body of a user, when the electronic device (e.g., the electronic device 100 of FIGS. 1A, 1B, and 1C is worn by the user. The plurality of slits S may be connected by penetrating each of layers. The conductive layer 833 may include the conductive patterns 820.

The conductive layer 833 may include the conductive patterns 820. The conductive patterns 820 may be connected to wires of first wires 215 (e.g., the first wires 215 of FIG. 2) and second wires 225 (e.g., the second wires 225 of FIG. 2). For example, each of conductive patterns disposed on the first pattern parts 830b disposed on the first strap (e.g., the first strap 150 of FIG. 1A) may be connected to wires of the first wires 215. Each of conductive patterns disposed on the second pattern parts 830c disposed on the second strap (e.g., the second strap 160 of FIG. 1A) may be connected to wires of the second wires 225. For another example, the conductive patterns 820 may be the first wires 215 or the second wires 225. For example, the first wires 215 may be extended, in the support plate 830, along a periphery of the plurality of slits S of the first pattern part 830b. The second wires 225 may be extended, in the support plate, along a periphery of a plurality of slits of the second pattern part 830c.

The support plate 830 for supporting a display panel of the deformable display 120, in a case of formed of a composite material, may replace a portion of the wires of the first wires 215 and the second wires 225, using a conductive pattern disposed in the inside. In a case that the first wires 215 and the second wires 225 are disposed in a bezel area or an inactive area, when the number of wires increases, a width of a bezel may increase. In a case that wire is disposed through the support plate 830 disposed below the display panel, the width of the bezel may be reduced. Conductive patterns disposed through the support plate 830 may be connected to a scan line and a data line of the display 120. The conductive patterns 820 may be extended along a periphery of the slits S. Each of the conductive patterns 820 may be connected to a scan line and a data line at a specified location.

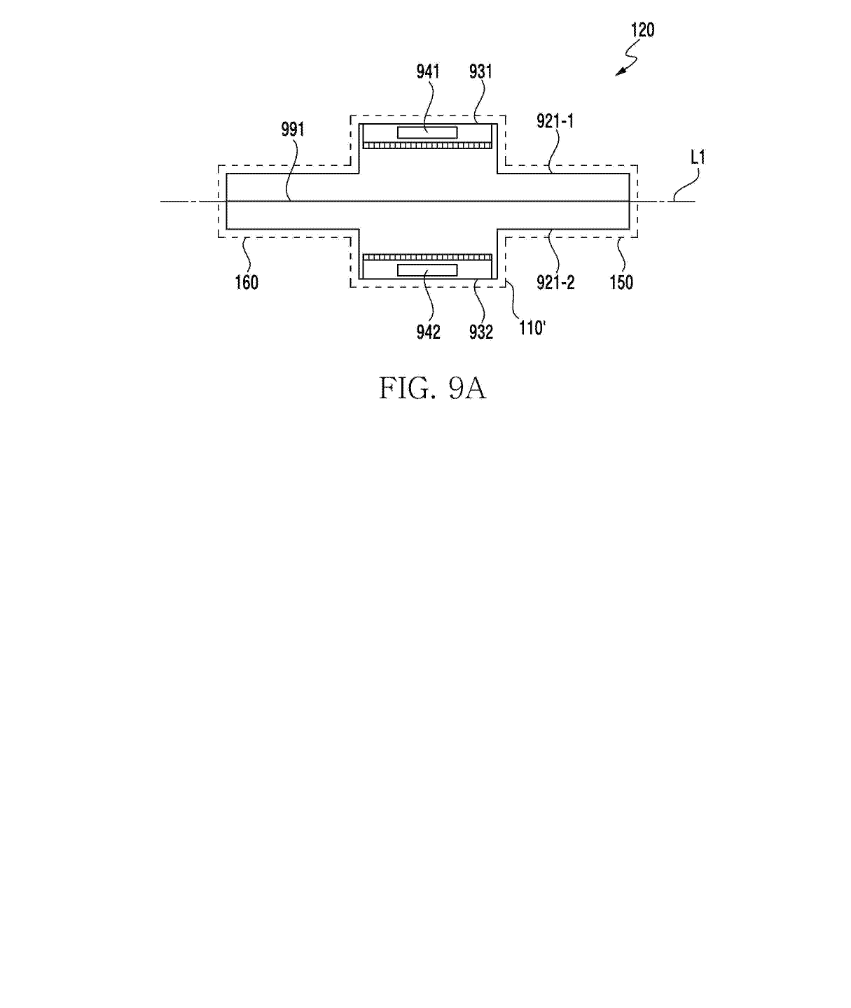

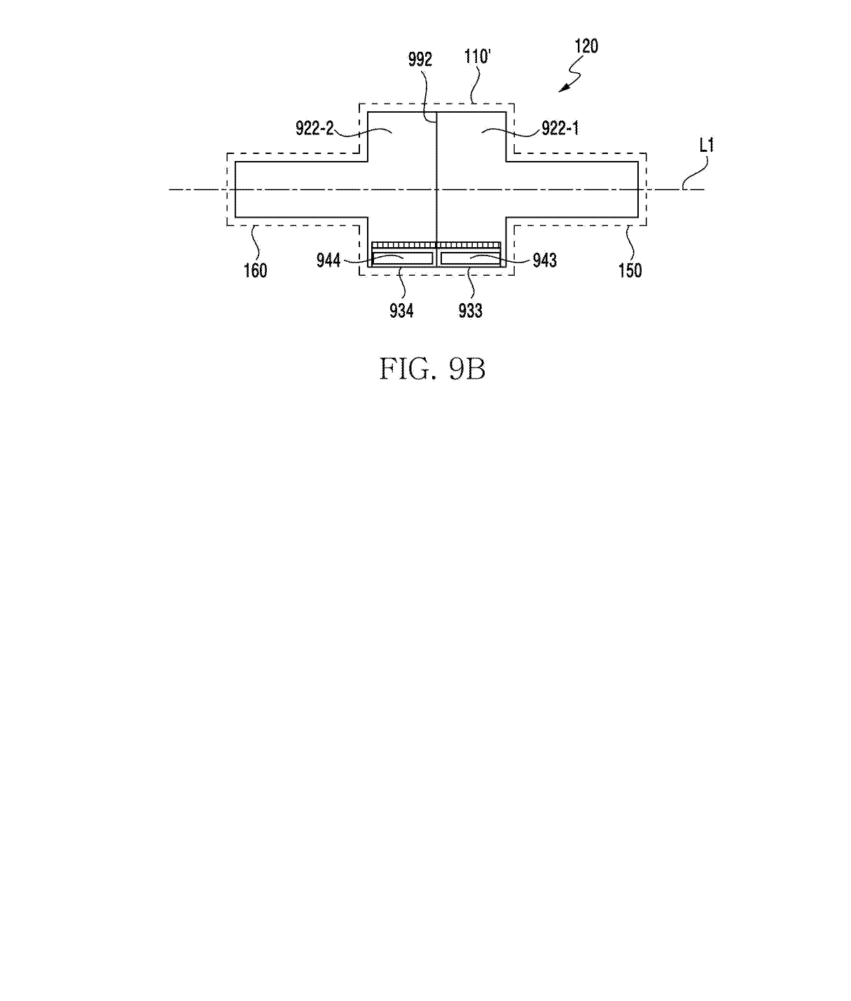

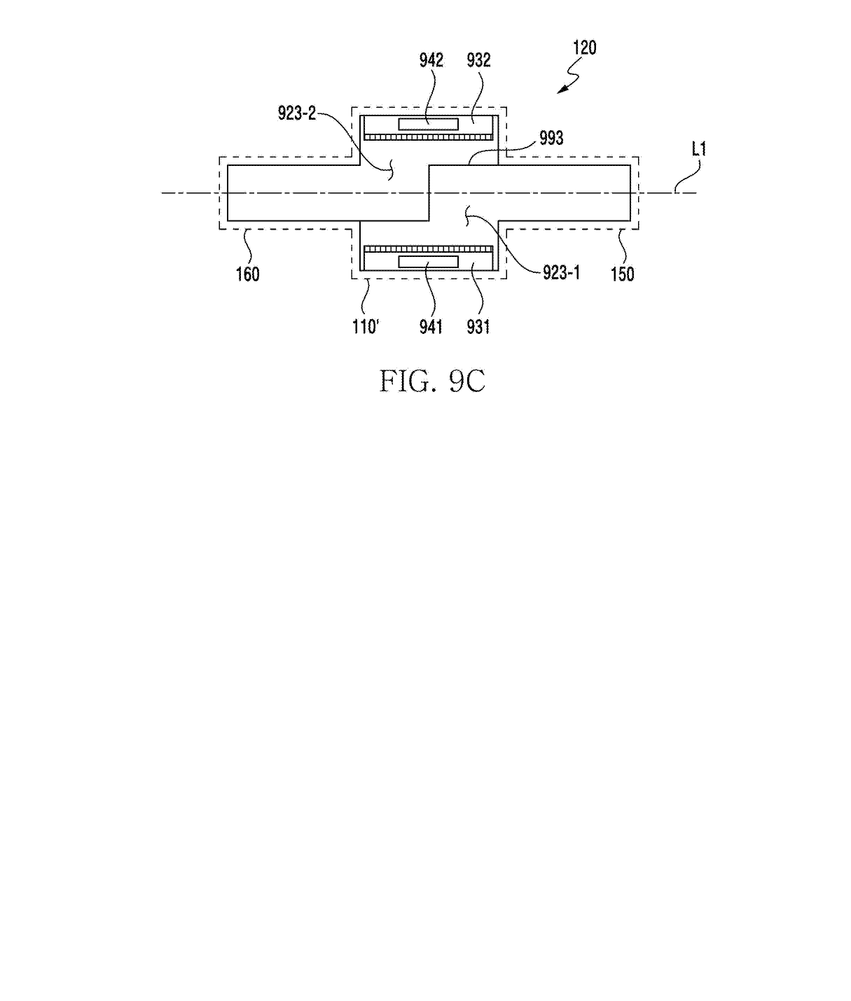

FIGS. 9A, 9B, and 9C represent an exemplary disposition of a plurality of driving circuitries included in a display.

Referring to FIG. 9A, a display 120 may include a first display area 921-1 and a second display area 921-2. The first display area 921-1 may be an area of the display 120 located in a first direction with respect to a virtual line crossing centers of a first strap 150 and a second strap 160. A first bending part 931 may be extended from the first display area 921-1.

The second display area 921-2 may be an area of the display 120 located in a second direction opposite to the first direction with respect to a virtual line L1 crossing centers of the first strap 150 and the second strap 160. A second bending part 932 may be extended from the second display area 921-2.

The first display area 921-1 and the second display area 921-2 may be divided in an area on a frame 110′. A boundary 991 between the first display area 921-1 and the second display area 921-2 may be disposed on the frame 110′. The boundary 991 between the first display area 921-1 and the second display area 921-2 may be the virtual line L1 crossing centers of the first strap 150 and the second strap 160. The boundary 991 dividing the first display area 921-1 and the second display area 921-2 may divide a display area of the display 120 on the frame 110′ in half.

The first driving circuitry 941 may drive a pixel in the first display area 921-1. The first driving circuitry 941 may be connected to pixels in the first display area 921-1 through wires extending through the first bending part 931 extending from a panel of the display 120.

The second driving circuitry 942 may drive a pixel in the second display area 921-2. The second driving circuitry 942 may be connected to pixels in the second display area 921-2 through wires extending through the second bending part 932 extending from the panel of the display 120.

Referring to FIG. 9B, a display 120 may include a first display area 922-1 and a second display area 922-2. The display of FIG. 9B may be similar to the display of FIGS. 4A and/or 4B except for a shape of the display disposed on a frame 110′. Descriptions of portions similar to the structures of FIGS. 4A and/or 4B are omitted. The first display area 922-1 may include a portion of an area of the display 120 disposed on the frame 110′ and at least a portion of the display 120 disposed on a first strap 150. The first display area 922-1 may be an area of the display 120 located in a direction that is perpendicular to a virtual line crossing centers of the first strap 150 and a second strap 160 and that faces the first strap 150 from a line passing through a center of the frame 110′. The second display area 922-2 may be an area located in a direction that is perpendicular to the virtual line crossing the centers of the first strap 150 and the second strap 160 and that faces the second strap 160 from the line passing through the center of the frame 110′. A first bending part 933 may be extended from the first display area 922-1.

The second display area 922-2 may include another portion of the area of the display 120 disposed on the frame 110′ and an area of the display 120 disposed on the second strap 160. The second display area 922-2 may be the area of the display 120 located in the direction that is perpendicular to a virtual line L1 crossing the centers of the first strap 150 and the second strap 160 and that faces the second strap 160 from the line passing through the center of the frame 110′. A second bending part 934 may be extended from the second display area 922-2.

The first display area 922-1 and the second display area 922-2 may be divided in a display area on the frame 110′. A boundary 992 between the first display area 922-1 and the second display area 922-2 may be disposed on the frame 110′. The boundary 992 between the first display area 922-1 and the second display area 922-2 may be perpendicular to the virtual line L1 crossing the centers of the first strap 150 and the second strap 160 and may pass through the center of the frame 110′. The boundary 992 dividing the first display area 922-1 and the second display area 922-2 may divide a display area of the display 120 on the frame 110′ in half.

First driving circuitry 943 may drive a pixel in the first display area 922-1. The first driving circuitry 943 may be connected to pixels in the first display area 921-1 through wires extending through the first bending part 933 extending from a panel of the display 120. The first driving circuitry 943 and second driving circuitry 944 may be disposed on a side of the frame 110′ with respect to the virtual line L1. The boundary 992 may be disposed between the first driving circuitry 943 and the second driving circuitry 944.

The second driving circuitry 944 may drive a pixel in the second display area 922-2. The second driving circuitry 944 may be connected to pixels in the second display area 922-2 through wires extending through the second bending part 934 extending from the panel of the display 120.

Referring to FIG. 9C, a display 120 may include a first display area 923-1 and a second display area 923-2. The display of FIG. 9C may be similar to the display of FIG. 3A except for a shape of the display disposed on a frame 110′. Descriptions of portions similar to the structure of FIG. 3A are omitted. The first display area 923-1 may include a portion of an area of the display 120 disposed on the frame 110′ and at least a portion of the display 120 disposed on a first strap 150. The first display area 923-1 and the second display area 923-2 may be divided along a line separating a center of the frame 110′ while extending from a point between the first strap 150 and a second bending part 932 to a point between a second strap 160 and a first bending part 931. The first bending part 931 may be extended from the first display area 923-1. The second bending part 932 may be extended from the second display area 923-2.

The first display area 923-1 and the second display area 923-2 may be divided in a display area on the frame 110′. A boundary 993 between the first display area 923-1 and the second display area 923-2 may be disposed on the frame 110′. The boundary 993 between the first display area 923-1 and the second display area 923-2 may be the line separating the center of the frame 110′ while extending from the point between the first strap 150 and the second bending part 932 to the point between the second strap 160 and the first bending part 931 in the first display area 923-1 and the second display area 923-2. The boundary 993 may include a portion that is bent while extending from the point between the first strap 150 and the second bending part 932 to the point between the second strap 160 and the first bending part 931. The boundary 993 that divides the first display area 923-1 and the second display area 923-2 may divide a display area of the display 120 on the frame 110′ in half. The boundary 993 may be disposed between first driving circuitry 941 and second driving circuitry 942. The boundary 993 may be disposed between the first strap 150 and the second strap 160.

The first driving circuitry 941 may drive a pixel in the first display area 923-1. The first driving circuitry 941 may be connected to pixels in the first display area 923-1 through wires extending through the first bending part 931 extending from a panel of the display 120. The first driving circuitry 941 and the second driving circuitry 942 may be disposed on a side of the frame 110′ with respect to a virtual line L1.

The second driving circuitry 942 may drive a pixel in the second display area 923-2. The second driving circuitry 942 may be connected to pixels in the second display area 923-2 through wires extending through the second bending part 932 extending from the panel of the display 120.

According to an embodiment, an electronic device may include driving circuitry of which a size is increased due to an increase in wires for an extended display. When the size of the driving circuitry increases, it may be difficult to dispose electrical components inside the electronic device or an electronic object such as a battery. When the size of the driving circuitry increases, a width of a bending portion (e.g., a bending portion of a COP) through which a wire passes increases, so a bezel of the display may increase.

The technical problems to be achieved in this document are not limited to those described above, and other technical problems not mentioned herein will be clearly understood by those having ordinary knowledge in the art to which the present disclosure belongs.

According to the above-described embodiment, a wearable electronic device (e.g., the wearable electronic device 100 of FIG. 2) may include a frame (e.g., the frame 110 of FIG. 2). The wearable electronic device 100 may include a first strap (e.g., the first strap 150 of FIG. 2) extending from a portion of a side surface of the frame 110 and a second strap 160 extending from another portion of the side surface of the frame 110 in a direction opposite to an extension direction of the first strap 150. The wearable electronic device 100 may include a display 120 (e.g., the display 120 of FIG. 2) disposed on the frame 110, the first strap 150, and the second strap 160.

The display 120 may include a display panel 201 (e.g., the display panel 201 of FIG. 2) including light emitting elements, a first bending part 211 (e.g., the first bending part 211 of FIG. 2) bent into a space surrounded by the frame 110 as a substrate of the display panel 201 extends from a side of the display panel 201, and a second bending part 221 (e.g., the second bending part 221 of FIG. 2) bent into the space as the substrate of the display panel 201 extends from another side of the display panel 201. The display may further include first driving circuitry 221 disposed on the substrate extending through the first bending part 211, and second driving circuitry 222 disposed on the substrate extending through the second bending part 221. The display may include first wires 215 connected from the first driving circuitry 221 to a scan line 231 and a data line 232 in a first display area of the display 120 through the first bending part 211, and second wires 225 connected from the second driving circuitry 222 to a scan line 231 and data lines 232 in a second display area of the display 120 through the second bending part 221.

According to an embodiment, the first display area 300-1 or 400-1 may include an area including a side of the display panel 201 and an area of the display panel 201 disposed on the first strap 150.

The second display area 300-2 or 400-2 may include an area including another side of the display panel 201 and an area of the display panel 201 disposed on the second strap 160.

According to an embodiment, the first bending part 211 may be disposed on a side surface of the display panel 201 located in a first direction with respect to a virtual line L1 crossing centers of the first strap 150 and the second strap 160.

According to an embodiment, the second bending part 221 may be disposed on another side surface of the display panel 201 located in a second direction opposite to the first direction with respect to the virtual line L1.

According to an embodiment, wires in the first wires 215 may be extended along the side surface of the display panel 201 disposed on the first strap 150 and a portion of the frame 110, through the first bending part 211, and wires in the second wires 225 may be extended along the side surface of the display panel 201 disposed on the second strap 160 and another portion of the frame 110 through the second bending part 221.

According to an embodiment, a width of the first bending part 211 and a width of the second bending part 221 may be the same.

According to an embodiment, the first bending part 211 and the second bending part 221 may be disposed on a side surface of the display panel 201 located in the same direction with respect to a virtual line crossing centers of the first strap 150 and the second strap 160.

According to an embodiment, wires in the first wires 215 may be extended along the side surface of the display panel 201 disposed on the first strap 150 and a portion of the frame 110, through the first bending part 211.

Wires in the second wires 225 may be extended along the side surface of the display panel 201 disposed on the second strap 160 and another part of the frame 110, through the second bending part 221.

The first strap 150 may be closer to the first bending part 211 among the first bending part 211 and the second bending part.

According to an embodiment, the first display area 500-1 may be a portion of a display area of the display 120 corresponding to the frame 110.

The second display area 500-2 may be another portion of the display area of the display 120 corresponding to the first strap 150 and the second strap 160.

According to an embodiment, wires in the first wires 215 may be extended along a side surface of the frame 110 through the first bending part 211.

Wires in the second wires 225 may be extended along a side surface of the display panel 201 on the first strap 150 and the second strap 160, through the second bending part 221.

According to an embodiment, the second driving circuitry 222 may be configured to inactivate the second display area while the first display area is activated through the first driving circuitry 221.

According to an embodiment, the display 120 may include a first portion disposed on the frame 110 and maintaining a shape of the first portion, and a second portion disposed on the first strap 150 and the second strap 160 and deformable. According to an embodiment, the first strap 150 and the second strap 160 may wrap around a part of a body of a user, when the wearable electronic device 100 is worn on the part of the body.

According to an embodiment, the wearable electronic device 100 may include a printed circuit board 610 disposed between the first driving circuitry 221 and the second driving circuitry 222 in the space and on which at least one processor is disposed.

The wearable electronic device 100 may further include a flexible printed circuit board 620 including a connector connected to the printed circuit board.

The display 120 may further include a first bonding portion 631 disposed on the substrate extending through the first bending part 211 and a second bonding portion 632 disposed on the substrate extending through the second bending part 221. The first bending part 211 and the second bending part 221 may be connected to the flexible printed circuit board 620 through the first bonding portion 631 and the second bonding portion 632 and the first driving circuitry 221 and the second driving circuitry 222 may be electrically connected to the at least one processor 601.

The display panel 201 may further include a support plate 830 supporting a layer on which the light emitting elements are disposed.

The support plate may include a planar part 830a disposed on the frame 110, a first pattern part 830b including a plurality of slits S and disposed on the first strap 150, and a second pattern part 830c including the plurality of slits S and disposed on the second strap 160.

The first wires 215 may be extended along a periphery of the plurality of slits S of the first pattern part 830b in the support plate, and the second wires 225 may be extended along a periphery of the plurality of slits S of the second pattern part 830c in the support plate.

The wearable electronic device may further include a battery disposed between the first driving circuitry 221 and the second driving circuitry 222 and spaced apart from the substrate extending through the first bending part 211 and the second bending part 221.

The wearable electronic device 100 may include a frame 110, a plurality of straps 150 and 160 extended from a portion of a side wall of the frame 110, and a display 120 disposed on the frame 110 and the plurality of straps 150 and 160. The display 120 may include first driving circuitry 221 disposed into a space surrounded by the side wall of the frame 110 and configured to control driving of pixels in a first display area of the display 120, and second driving circuitry 222 disposed into the space and configured to control driving of pixels in a second display area of the display 120.

The frame 110 may include slits formed in partition walls 711 and 712 of the frame 110 through which a portion of the display 120 disposed on the plurality of straps 150 and 160 passes.

The slits may be disposed on inactive areas of the display 120.

The first display area 720a may be disposed between the inactive areas.

The second display area 720b or 720c may be disposed on the strap.

According to an embodiment, a printed circuit board 610 disposed between the first driving circuitry 221 and the second driving circuitry 222 in the space and on which at least one processor 601 is disposed, and a flexible printed circuit board 620 connected to the printed circuit board may be further included. The first driving circuitry 221 and the second driving circuitry 222 may be electrically connected to the at least one processor.

The wearable electronic device 100 may further include memory 1010 including instructions.

The instructions, when the at least one processor 601 is executed, may cause the wearable electronic device 100 to inactivate the second display area through the second driving circuitry 222, while the first display area is activated through the first driving circuitry 221.

The display 120 may include a first portion disposed on the frame 110 and maintaining a shape of the first portion, and a second portion disposed on the first strap 150 and the second strap 160 and deformable, and the first strap 150 and the second strap 160 may wrap around a part of a body of a user, when the wearable electronic device 100 is worn on the part of the body.

The effects that may be obtained from the present disclosure are not limited to those described above, and any other effects not mentioned herein will be clearly understood by those having ordinary knowledge in the art to which the present disclosure belongs.

FIG. 10 is a block diagram illustrating an electronic device 1001 in a network environment 1000 according to various embodiments.

Referring to FIG. 10, the electronic device 1001 in the network environment 1000 may communicate with an electronic device 1002 via a first network 1098 (e.g., a short-range wireless communication network), or at least one of an electronic device 1004 or a server 1008 via a second network 1099 (e.g., a long-range wireless communication network). According to an embodiment, the electronic device 1001 may communicate with the electronic device 1004 via the server 1008. According to an embodiment, the electronic device 1001 may include a processor 1020, memory 1030, an input module 1050, a sound output module 1055, a display module 1060, an audio module 1070, a sensor module 1076, an interface 1077, a connecting terminal 1078, a haptic module 1079, a camera module 1080, a power management module 1088, a battery 1089, a communication module 1090, a subscriber identification module (SIM) 1096, or an antenna module 1097. In some embodiments, at least one of the components (e.g., the connecting terminal 1078) may be omitted from the electronic device 1001, or one or more other components may be added in the electronic device 1001. In some embodiments, some of the components (e.g., the sensor module 1076, the camera module 1080, or the antenna module 1097) may be implemented as a single component (e.g., the display module 1060).

The processor 1020 may execute, for example, software (e.g., a program 1040) to control at least one other component (e.g., a hardware or software component) of the electronic device 1001 coupled with the processor 1020 and may perform various data processing or computation. According to an embodiment, as at least part of the data processing or computation, the processor 1020 may store a command or data received from another component (e.g., the sensor module 1076 or the communication module 1090) in volatile memory 1032, process the command or the data stored in the volatile memory 1032, and store resulting data in non-volatile memory 1034. According to an embodiment, the processor 1020 may include a main processor 1021 (e.g., a central processing unit (CPU) or an application processor (AP)), or an auxiliary processor 1023 (e.g., a graphics processing unit (GPU), a neural processing unit (NPU), an image signal processor (ISP), a sensor hub processor, or a communication processor (CP)) that is operable independently from, or in conjunction with, the main processor 1021. For example, when the electronic device 1001 includes the main processor 1021 and the auxiliary processor 1023, the auxiliary processor 1023 may be adapted to consume less power than the main processor 1021, or to be specific to a specified function. The auxiliary processor 1023 may be implemented as separate from, or as part of the main processor 1021.

The auxiliary processor 1023 may control at least some of functions or states related to at least one component (e.g., the display module 1060, the sensor module 1076, or the communication module 1090) among the components of the electronic device 1001, instead of the main processor 1021 while the main processor 1021 is in an inactive (e.g., sleep) state, or together with the main processor 1021 while the main processor 1021 is in an active state (e.g., executing an application). According to an embodiment, the auxiliary processor 1023 (e.g., an image signal processor or a communication processor) may be implemented as part of another component (e.g., the camera module 1080 or the communication module 1090) functionally related to the auxiliary processor 1023. According to an embodiment, the auxiliary processor 1023 (e.g., the neural processing unit) may include a hardware structure specified for artificial intelligence model processing. An artificial intelligence model may be generated by machine learning. Such learning may be performed, e.g., by the electronic device 1001 where the artificial intelligence is performed or via a separate server (e.g., the server 1008). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 1030 may store various data used by at least one component (e.g., the processor 1020 or the sensor module 1076) of the electronic device 1001. The various data may include, for example, software (e.g., the program 1040) and input data or output data for a command related thereto. The memory 1030 may include the volatile memory 1032 or the non-volatile memory 1034.

The program 1040 may be stored in the memory 1030 as software, and may include, for example, an operating system (OS) 1042, middleware 1044, or an application 1046.

The input module 1050 may receive a command or data to be used by another component (e.g., the processor 1020) of the electronic device 1001, from the outside (e.g., a user) of the electronic device 1001. The input module 1050 may include, for example, a microphone, a mouse, a keyboard, a key (e.g., a button), or a digital pen (e.g., a stylus pen).

The sound output module 1055 may output sound signals to the outside of the electronic device 1001. The sound output module 1055 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 1060 may visually provide information to the outside (e.g., a user) of the electronic device 1001. The display module 1060 may include, for example, a display, a hologram device, or a projector and control circuitry to control a corresponding one of the display, hologram device, and projector. According to an embodiment, the display module 1060 may include a touch sensor adapted to detect a touch, or a pressure sensor adapted to measure the intensity of force incurred by the touch.

The audio module 1070 may convert a sound into an electrical signal and vice versa. According to an embodiment, the audio module 1070 may obtain the sound via the input module 1050 or output the sound via the sound output module 1055 or a headphone of an external electronic device (e.g., an electronic device 1002) directly (e.g., wiredly) or wirelessly coupled with the electronic device 1001.

The sensor module 1076 may detect an operational state (e.g., power or temperature) of the electronic device 1001 or an environmental state (e.g., a state of a user) external to the electronic device 1001 and then generate an electrical signal or data value corresponding to the detected state. According to an embodiment, the sensor module 1076 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 1077 may support one or more specified protocols to be used for the electronic device 1001 to be coupled with the external electronic device (e.g., the electronic device 1002) directly (e.g., wiredly) or wirelessly. According to an embodiment, the interface 1077 may include, for example, a high-definition multimedia interface (HDMI), a universal serial bus (USB) interface, a secure digital (SD) card interface, or an audio interface.

A connecting terminal 1078 may include a connector via which the electronic device 1001 may be physically connected with the external electronic device (e.g., the electronic device 1002). According to an embodiment, the connecting terminal 1078 may include, for example, an HDMI connector, a USB connector, an SD card connector, or an audio connector (e.g., a headphone connector).

The haptic module 1079 may convert an electrical signal into a mechanical stimulus (e.g., a vibration or a movement) or electrical stimulus which may be recognized by a user via his tactile sensation or kinesthetic sensation. According to an embodiment, the haptic module 1079 may include, for example, a motor, a piezoelectric element, or an electric stimulator.

The camera module 1080 may capture a still image or moving images. According to an embodiment, the camera module 1080 may include one or more lenses, image sensors, image signal processors, or flashes.

The power management module 1088 may manage power supplied to the electronic device 1001. According to an embodiment, the power management module 1088 may be implemented as at least part of, for example, a power management integrated circuit (PMIC).

The battery 1089 may supply power to at least one component of the electronic device 1001. According to an embodiment, the battery 1089 may include, for example, a primary cell which is not rechargeable, a secondary cell which is rechargeable, or a fuel cell.

The communication module 1090 may support establishing a direct (e.g., wired) communication channel or a wireless communication channel between the electronic device 1001 and the external electronic device (e.g., the electronic device 1002, the electronic device 1004, or the server 1008) and performing communication via the established communication channel. The communication module 1090 may include one or more communication processors that are operable independently from the processor 1020 (e.g., the application processor (AP)) and supports a direct (e.g., wired) communication or a wireless communication. According to an embodiment, the communication module 1090 may include a wireless communication module 1092 (e.g., a cellular communication module, a short-range wireless communication module, or a global navigation satellite system (GNSS) communication module) or a wired communication module 1094 (e.g., a local area network (LAN) communication module or a power line communication (PLC) module). A corresponding one of these communication modules may communicate with the external electronic device via the first network 1098 (e.g., a short-range communication network, such as Bluetooth™, wireless-fidelity (Wi-Fi) direct, or infrared data association (IrDA)) or the second network 1099 (e.g., a long-range communication network, such as a legacy cellular network, a 5G network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 1092 may identify and authenticate the electronic device 1001 in a communication network, such as the first network 1098 or the second network 1099, using subscriber information (e.g., international mobile subscriber identity (IMSI)) stored in the subscriber identification module 1096.

The wireless communication module 1092 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 1092 may support a high-frequency band (e.g., the mmWave band) to achieve, e.g., a high data transmission rate. The wireless communication module 1092 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 1092 may support various requirements specified in the electronic device 1001, an external electronic device (e.g., the electronic device 1004), or a network system (e.g., the second network 1099). According to an embodiment, the wireless communication module 1092 may support a peak data rate (e.g., 20Gbps or more) for implementing eMBB, loss coverage (e.g., 1064dB or less) for implementing mMTC, or U-plane latency (e.g., 0.5ms or less for each of downlink (DL) and uplink (UL), or a round trip of 10ms or less) for implementing URLLC.

The antenna module 1097 may transmit or receive a signal or power to or from the outside (e.g., the external electronic device) of the electronic device 1001. According to an embodiment, the antenna module 1097 may include an antenna including a radiating element composed of a conductive material or a conductive pattern formed in or on a substrate (e.g., a printed circuit board (PCB)). According to an embodiment, the antenna module 1097 may include a plurality of antennas (e.g., array antennas). In such a case, at least one antenna appropriate for a communication scheme used in the communication network, such as the first network 1098 or the second network 1099, may be selected, for example, by the communication module 1090 (e.g., the wireless communication module 1092) from the plurality of antennas. The signal or the power may then be transmitted or received between the communication module 1090 and the external electronic device via the selected at least one antenna. According to an embodiment, another component (e.g., a radio frequency integrated circuit (RFIC)) other than the radiating element may be additionally formed as part of the antenna module 1097.

According to various embodiments, the antenna module 1097 may form a mmWave antenna module. According to an embodiment, the mmWave antenna module may include a printed circuit board, an RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 1001 and the external electronic device 1004 via the server 1008 coupled with the second network 1099. Each of the electronic devices 1002 or 1004 may be a device of a same type as, or a different type, from the electronic device 1001. According to an embodiment, all or some of operations to be executed at the electronic device 1001 may be executed at one or more of the external electronic devices 1002, 1004, or 1008. For example, if the electronic device 1001 should perform a function or a service automatically, or in response to a request from a user or another device, the electronic device 1001, instead of, or in addition to, executing the function or the service, may request the one or more external electronic devices to perform at least part of the function or the service. The one or more external electronic devices receiving the request may perform the at least part of the function or the service requested, or an additional function or an additional service related to the request and transfer an outcome of the performing to the electronic device 1001. The electronic device 1001 may provide the outcome, with or without further processing of the outcome, as at least part of a reply to the request. To that end, a cloud computing, distributed computing, mobile edge computing (MEC), or client-server computing technology may be used, for example. The electronic device 1001 may provide ultra low-latency services using, e.g., distributed computing or mobile edge computing. In another embodiment, the external electronic device 1004 may include an internet-of-things (IoT) device. The server 1008 may be an intelligent server using machine learning and/or a neural network. According to an embodiment, the external electronic device 1004 or the server 1008 may be included in the second network 1099. The electronic device 1001 may be applied to intelligent services (e.g., smart home, smart city, smart car, or healthcare) based on 5G communication technology or IoT-related technology.

The electronic device according to various embodiments may be one of various types of electronic devices. The electronic devices may include, for example, a portable communication device (e.g., a smartphone), a computer device, a portable multimedia device, a portable medical device, a camera, a wearable device, or a home appliance. According to an embodiment of the disclosure, the electronic devices are not limited to those described above.

It should be appreciated that various embodiments of the present disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” or “connected with” another element (e.g., a second element), it means that the element may be coupled with the other element directly (e.g., wiredly), wirelessly, or via a third element.

As used in connection with various embodiments of the disclosure, the term “module” may include a unit implemented in hardware, software, or firmware, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

Various embodiments as set forth herein may be implemented as software (e.g., the program 1040) including one or more instructions that are stored in a storage medium (e.g., internal memory 1036 or external memory 1038) that is readable by a machine (e.g., the electronic device 1001). For example, a processor (e.g., the processor 1020) of the machine (e.g., the electronic device 1001) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a compiler or a code executable by an interpreter. The machine-readable storage medium may be provided in the form of a non-transitory storage medium. Wherein, the term “non-transitory” simply means that the storage medium is a tangible device, and does not include a signal (e.g., an electromagnetic wave), but this term does not differentiate between a case in which data is semi-permanently stored in the storage medium and a case in which the data is temporarily stored in the storage medium.

According to an embodiment, a method according to various embodiments of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore™), or between two user devices (e.g., smart phones) directly. If distributed online, at least part of the computer program product may be temporarily generated or at least temporarily stored in the machine-readable storage medium, such as memory of the manufacturer’s server, a server of the application store, or a relay server.

According to various embodiments, each component (e.g., a module or a program) of the above-described components may include a single entity or multiple entities, and some of the multiple entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

What is claimed is:

1. A wearable electronic device comprising :
a frame;
a first strap extending from a first portion of a side surface of the frame and a second strap extending from a second portion of the side surface of the frame in a direction opposite to an extension direction of the first strap; and
a flexible display disposed on the frame, the first strap, and the second strap;
wherein the flexible display comprises:
a display panel;
a first bending part extending from a first side of the display panel and bent into a space surrounded by the frame;
a second bending part extending from a second side of the display panel and bent into the space in the frame;
first driving circuitry disposed on a substrate of the display panel extending through the first bending part;
second driving circuitry disposed on a substrate of the display panel extending through the second bending part;
first wires extending from the first driving circuitry and electrically connected to scan lines and data lines in a first display area of the display panel through the first bending part; and
second wires extending from the second driving circuitry and electrically connected to scan lines and data lines in a second display area of the display panel through the second bending part.

2. The wearable electronic device of claim 1, wherein the first display area comprises a portion of the display panel disposed on the frame adjacent the first side of the display panel and a portion of the display panel disposed on the first strap, and
wherein the second display area comprises a portion of the display panel disposed on the frame adjacent the second side of the display panel and a portion of the display panel disposed on the second strap.

3. The wearable electronic device of claim 1, wherein the first bending part is disposed on a first side surface of the display panel located in a first direction with respect to a virtual line crossing centers of the first strap and the second strap, and
wherein the second bending part is disposed on a second side surface of the display panel located in a second direction opposite to the first direction with respect to the virtual line.

4. The wearable electronic device of claim 3, wherein the first wires are extended along the side surface of the display panel disposed on the first strap and along a first portion of the frame, through the first bending part, and
wherein the second wires are extended along the side surface of the display panel disposed on the second strap and along a second portion of the frame through the second bending part.

5. The wearable electronic device of claim 1, wherein a width of the first bending part and a width of the second bending part are equal.

6. The wearable electronic device of claim 1, wherein the first bending part and the second bending part are disposed on a side surface of the display panel located in the same direction with respect to a virtual line crossing centers of the first strap and the second strap.

7. The wearable electronic device of claim 6, wherein the first wires are extended along the side surface of the display panel disposed on the first strap and along a first portion of the frame, through the first bending part,
wherein the second wires are extended along the side surface of the display panel disposed on the second strap and along a second portion of the frame, through the second bending part, and
wherein the first strap is closer to the first bending part than to the second bending part.

8. The wearable electronic device of claim 1, wherein the first display area is a portion of the display panel disposed on the frame, and
wherein the second display area comprises portions of the display panel disposed on the first strap and the second strap.

9. The wearable electronic device of claim 8, wherein the first wires are extended along a side surface of the frame through the first bending part, and
wherein the second wires are extended along edges of the first strap and the second strap through the second bending part.

10. The wearable electronic device of claim 8, wherein the second driving circuitry is configured to inactivate the second display area, while the first driving circuitry drives the first display area.

11. The wearable electronic device of claim 1, wherein the flexible display comprises a first portion disposed on the frame and maintaining a fixed shape, and a second portion disposed on the first strap and the second strap and deformable, and
wherein the first strap and the second strap wrap around a body part of a user, when the wearable electronic device is worn on the body part.

12. The wearable electronic device of claim 1, further comprising:
a printed circuit board disposed in the space surrounded by the frame and positioned between the first driving circuitry and the second driving circuitry, the printed circuit board comprising at least one processor; and
a flexible printed circuit board comprising a connector connected to the printed circuit board;
wherein the flexible display comprises a first bonding portion disposed on the substrate extending through the first bending part and a second bonding portion disposed on the substrate extending through the second bending part, and
wherein the first bending part and the second bending part are connected to the flexible printed circuit board through the first bonding portion and the second bonding portion such that the first driving circuitry and the second driving circuitry are electrically connected to the at least one processor.

13. The wearable electronic device of claim 1, wherein the display panel further comprises a support plate supporting a light-emitting layer, and
wherein the support plate comprises a planar part disposed on the frame, a first pattern part comprising a plurality of slits and disposed on the first strap, and a second pattern part comprising the plurality of slits and disposed on the second strap.

14. The wearable electronic device of claim 13, wherein the first wires are extended along a periphery of the plurality of slits of the first pattern part in the support plate, and
wherein the second wires are extended along a periphery of the plurality of slits of the second pattern part in the support plate.

15. The wearable electronic device of claim 14, further comprising:
a battery disposed between the first driving circuitry and the second driving circuitry and spaced apart from the first bending part and the second bending part.

16. A wearable electronic device comprising:
a frame comprising a side wall;
a plurality of straps extending from the side wall of the frame; and
a display disposed on the frame and the plurality of straps;
wherein the display comprises:
a first driving circuitry disposed in a space surrounded by the side wall of the frame and configured to drive pixels in a first display area of the display; and
a second driving circuitry disposed in the space and configured to drive pixels in a second display area of the display;
wherein the frame comprises slits formed in partition walls of the frame through which a portion of the display disposed on the plurality of straps passes and the slits are disposed in inactive areas of the display.

17. The wearable electronic device of claim 16, wherein the first display area is disposed between the inactive areas, and
wherein the second display area is disposed on the plurality of straps.

18. The wearable electronic device of claim 16, further comprising:
a printed circuit board disposed in the space surrounded by the side wall of the frame and positioned between the first driving circuitry and the second driving circuitry, the printed circuit board comprising at least one processor; and
a flexible printed circuit board connected to the printed circuit board,
wherein the first driving circuitry and the second driving circuitry are electrically connected to the at least one processor.

19. The wearable electronic device of claim 18, further comprising memory including instructions,
wherein the instructions, when the at least one processor executes the instructions, cause the wearable electronic device to inactivate the second display area through the second driving circuitry, while the first driving circuitry drives the first display area.

20. The wearable electronic device of claim 16, wherein the display comprises a first portion disposed on the frame and maintaining a fixed shape, and a second portion disposed on the plurality of straps and deformable, and
wherein the plurality of straps wrap around a body part of a user, when the wearable electronic device is worn on the body part.
